(19) United States
(12) Patent Application Publication
(10) Pub. No.: US 2025/0098181 A1
(43) Pub. Date: Mar. 20, 2025

(54) INTEGRATED MEMORY CONTROLLER CIRCUITRY

(71) Applicant: Advanced Micro Devices, Inc., Santa Clara, CA (US)

(72) Inventors: Alan D. SMITH, Austin, TX (US); Samuel NAFFZIGER, Fort Collins, CO (US); Joe MACRI, Boxborough, MA (US); James R. MAGRO, Austin, TX (US); Vydhyanathan KALYANASUNDHARAM, Santa Clara, CA (US)

(21) Appl. No.: 18/829,848

(22) Filed: Sep. 10, 2024

Related U.S. Application Data
(60) Provisional application No. 63/538,950, filed on Sep. 18, 2023.
(60) Provisional application No. 63/539,020, filed on Sep. 18, 2023.
(60) Provisional application No. 63/538,451, filed on Sep. 14, 2023.

(51) Int. Cl. H10B 80/00; H01L 23/498; H01L 25/065; H01L 25/18

(52) U.S. Cl. CPC H10B 80/00; H01L 25/0657; H01L 25/18; H01L 23/49816; H01L 2225/06541

(57) ABSTRACT

A package device includes a processing device, memory dies and a memory controller. The memory controller die is coupled to the processing device and the memory dies. The memory controller die controls communication from the processing device to the memory dies and to an external memory device. The external memory device is external to the memory dies.

### CROSS REFERENCE TO RELATED APPLICATIONS

This application claims the benefit of U.S. provisional patent application Ser. No. 63/538,451, filed Sep. 14, 2023, U.S. provisional patent application Ser. No. 63/538,950, filed Sep. 18, 2023, and U.S. provisional patent application Ser. No. 63/539,020, filed Sep. 18, 2023, all of which are hereby incorporated herein by reference.

### TECHNICAL FIELD

Examples of the present disclosure generally relate to a memory stack-up including memory dies and a memory controller die, which controls communication to the memory dies of the memory stack-up and a memory device external to the memory stack-up.

### BACKGROUND

An electronic device includes a processing device and a stacked memory device. The processing device and the stacked memory device are mounted to an interposer. The memory device includes two or more stacked (e.g., vertically or horizontally stacked) memory dies. The processing device is further connected to an external memory device that is not included within the stacked memory device. Communication between the processing device and the stacked memory device, and between the processing device and the external memory device is controlled via different memory controllers. Accordingly, an electronic device that includes both a stacked memory device and an external memory device has increased complexity due to the increased number of memory controller circuitries and the corresponding increased routing with the processing die, increasing the design time and semiconductor manufacturing cost of the electronic device.

### SUMMARY

In one example, a package device includes a processing device, memory dies and a memory controller. The memory controller die is coupled to the processing device and the memory dies. The memory controller die controls communication from the processing device to the memory dies and to an external memory device. The external memory device is external to the memory dies.

In one example, a memory device includes memory dies, and a memory controller die connected to the memory dies, a processing device, and an external memory device. The external memory device is external to the memory dies. The memory controller die is configured to control communication from the processing device to the memory dies and the memory device.

In one example, a computer system includes a first processing device, and an integrated circuit device coupled to the first processing device, the first integrated circuit device including a second processing device, memory dies, a memory device external to the memory dies, and a memory controller die coupled to the second processing device, the memory dies, and the memory device. The memory controller die controls communication from the second processing device to the memory dies and the memory device.

In one example, a method includes receiving, at a memory controller die of a package device, a memory command from a processing device. The package device includes memory dies. The memory controller die is connected to the memory dies and a memory device that is external from the memory dies. The method further includes outputting the memory command to one of a memory die of memory dies based on the memory command being associated with the memory die or the memory device based on the memory command being associated with the memory device.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a block diagram of a package device having a processing device and a stacked memory device having a memory controller die disposed on an interposer, and an external memory device mounted to a package substrate.

FIG. 1B illustrates a block diagram of a package device having a processing device, a stacked memory device having a memory controller die, and an external memory device disposed on an interposer.

FIG. 1C illustrates a block diagram of a package device having a processing device and a stacked memory device having a memory controller die disposed on an interposer, and an external memory device mounted to a printed circuit board.

FIG. 1D illustrates a block diagram of a package device having a processing device and a stacked memory device having a memory controller die disposed on an interposer mounted to a first printed circuit board, and an external memory device mounted to a second printed circuit board.

FIG. 2A illustrates a block diagram of a portion of a package device, where separate channels are used to communicate with the stacked memory dies and the external memory device.

FIG. 2B illustrates a block diagram of a portion of a package device, where one or more shared channels are used to communicate with the stacked memory dies and the external memory device.

FIG. 3A illustrates a block diagram illustrating the communication of memory commands between the processing device, the stacked memory dies, and the external memory device.

FIG. 3B illustrates a block diagram illustrating the communication of memory commands between the processing device, the stacked memory dies, and the external memory device using one or more shared channels.

FIG. 3C illustrates a block diagram illustrating the communication of memory commands between the processing device, the stacked memory dies, and the external memory device using one or more shared channels.

FIG. 3D illustrates a block diagram illustrating the communication of memory commands between the processing device, the stacked memory dies, and the external memory device using one or more shared channels.

FIG. 3E illustrates a block diagram illustrating the communication of memory commands between the processing device, the stacked memory dies, and the external memory device using one or more shared channels.

FIG. 3F illustrates a block diagram illustrating the communication of memory commands between the processing device, the stacked memory dies, and the external memory device.

FIG. 3G illustrates a block diagram illustrating the communication of memory commands between the processing device, the stacked memory dies, and the external memory device, and corresponding interconnect circuitries.

FIG. 4A and FIG. 4B illustrate a block diagram illustrating the communication of memory commands between the processing device, the stacked memory dies, and the external memory device.

FIG. 5A and FIG. 5B illustrate a block diagram illustrating the communication of memory commands between the processing device, the stacked memory dies, and the external memory device using one or more shared channels.

FIG. 6A and FIG. 6B illustrate a block diagram illustrating the communication of memory commands between the processing device, the stacked memory dies, and the external memory device.

FIG. 7A and FIG. 7B illustrate a block diagram illustrating the communication of memory commands between the processing device, the stacked memory dies, and the external memory device.

FIG. 8A illustrates a block diagram of a processing circuitry and memory device circuitry.

FIG. 8B illustrates a block diagram of a processing circuitry and memory device circuitry.

FIG. 8C illustrates a block diagram of a processing circuitry and memory device circuitry.

FIG. 8D illustrates a block diagram of a processing circuitry and memory device circuitry.

FIG. 8E illustrates a block diagram of a processing circuitry and memory device circuitry.

FIG. 8F illustrates a block diagram of a processing circuitry and memory device circuitry.

FIG. 9A and FIG. 9B illustrates a block diagram illustrating the communication of memory commands between the processing device, the stacked memory dies, and the external memory device.

FIG. 10A and FIG. 10B illustrates a block diagram illustrating the communication of memory commands between the processing device, the stacked memory dies, and the external memory device.

FIG. 11 illustrates a block diagram of a computer system.

FIG. 12 illustrates a flowchart of a method for operating a memory controller die.

FIG. 13 illustrates a method for providing an integrated circuit device.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Electronic devices include one or more chip packages. A chip package includes one or more integrated circuit (IC) devices. The IC devices are mounted to and interconnected to each other via interposers and/or other substrates. In one example, the IC devices include a processing device, a stacked memory device, and an external memory device. A stacked memory device includes two or more memory dies that are horizontally or vertically stacked with each other. The external memory device is a memory device that is not included (e.g., external) within the stacked memory device. The stacked memory device includes a memory controller die that controls the communication of command signals and/or data signals between the processing device and the memory dies of the stacked memory device and the external memory device. In one example, the processing device outputs the command and data signals to the memory controller die. The memory controller die provides the command signals and/or data signals to one or more of the stacked memory dies or the external die. The memory controller die receives data signals from one or more the stacked memory dies and/or the external die, and provides the data signals to the processing device.

Using the memory controller die of the stacked memory device to control communication between a processing device, the stacked memory dies, and the external memory device reduces processing and routing complexity of the corresponding chip package and electronic device. Accordingly, the design and semiconductor manufacturing costs of the chip package and corresponding electronic device are reduced.

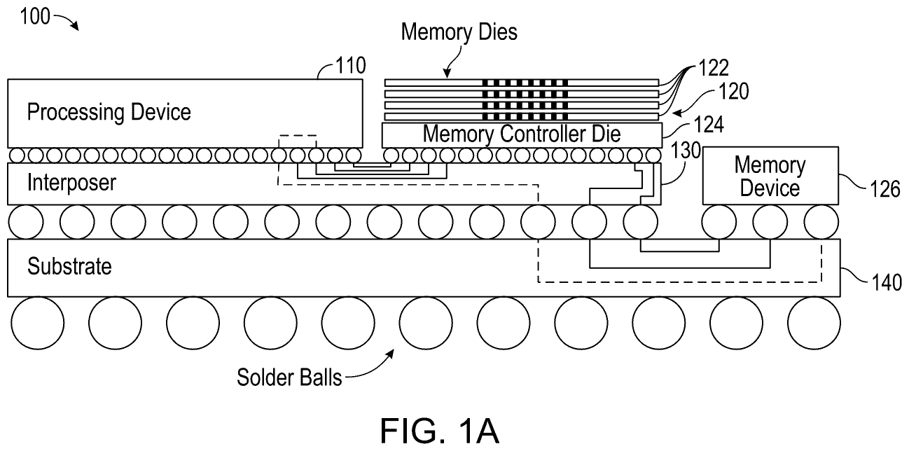

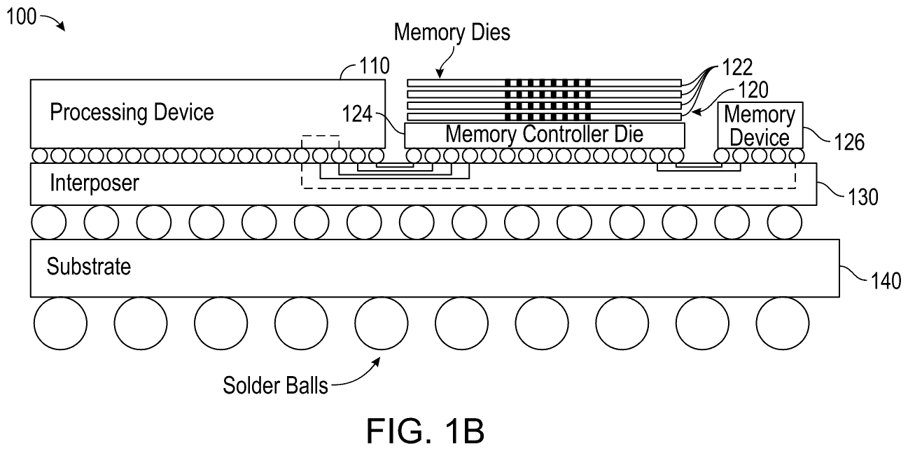

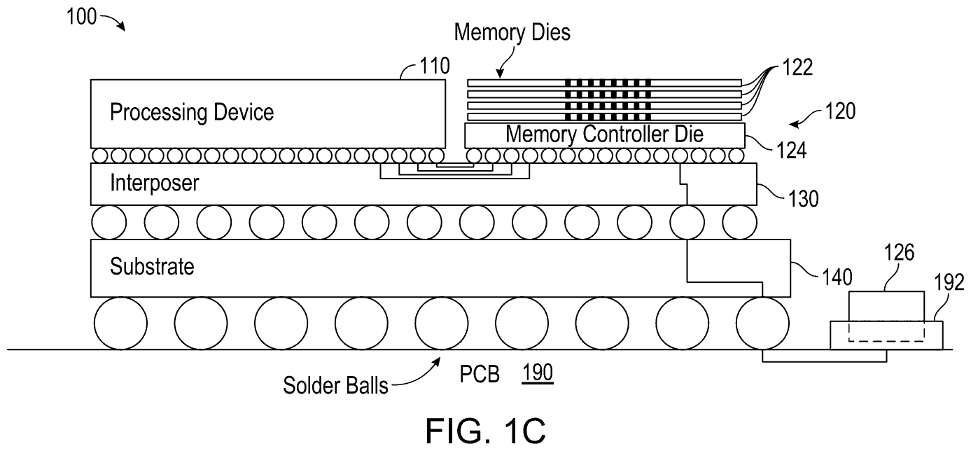

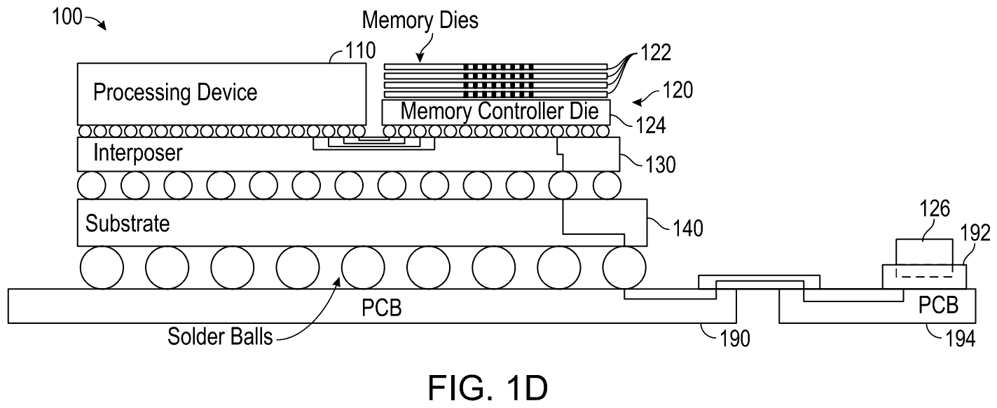

FIG. 1A illustrates a package device (or chip package) 100, according to one or more examples. The package device 100 includes a processing device 110, a memory device (e.g., a stacked memory device) 120, an interposer 130, and a substrate 140. The processing device 110 is a central processing unit (CPU) or a graphics processing unit (GPU), among others. The memory device 120 is connected to the processing device 110 through traces and/or vias within the interposer 130. The interposer 130 may be a silicon interposer, an organic interposer, or an organic interposer with embedded silicone bridges, among others. In other examples, the memory device 120 is disposed on top of the processing device 110. In one example, the memory device 120 may be connected to other processing devices and/or an external device(s) via the interposer 130 and/or the substrate 140.

The substrate 140 may be referred to as a package substrate, and is connected to the interposer 130 via solder balls. In one or more examples, the interposer 130 is omitted and the memory device 120 and the processing device 110 are directly mounted to (e.g., disposed on) the substrate 140.

The memory device 120 includes a memory controller die 124 and one or more memory dies 122. The memory dies 122 are interconnected with each other. The memory dies 122 are vertically stacked (e.g., mounted) on the memory controller die 124. In one example, the memory dies 122 are vertically stacked on each other and the memory controller die 124, forming a three-dimensional (3D) stack. In other examples, two or more of the memory dies 122 may be horizontally stacked with each other and/or the memory controller die 124. The memory controller die 124 is connected (e.g., communicatively connected) with the memory dies 122 to communicate signals (e.g., command and/or data signals) to and receive signals from the memory dies 122.

In one example, the memory device 120 is a high bandwidth memory (HBM) device. A high bandwidth memory device provides increased bandwidth and memory density as compared to conventional memory devices. In one such example, the memory device 120 includes up to 8-12 or more layers of dynamic random-access memory (DRAM) dies, or other memory devices, which are stacked (or connected in another way), as illustrated in FIG. 1A.

The memory controller die 124 is additionally connected to an external memory device 126. The external memory device 126 is not part of the memory device 120. The external memory device 126 is external to the stacked memory dies 122 of the memory device 120. The external memory device 126 is a different memory type than that of the memory dies 122. The external memory device 126 is comprised of a memory structure that is faster and/or higher capacity than the memory structure used to fabricate the memory dies 122 (such as DRAM dies) of the memory device 120. In one example, the external memory device 126 comprises double data rate synchronous dynamic random-access memory (DDR SDRAM) or memory of similar or faster speed and/or similar or higher capacity. In one example, the external memory is a lower power memory device than the memory dies 122. In the example depicted in FIG. 1A, the external memory device 126 is co-located within the package device 100. For example, the external memory device 126 may be mounted to the substrate 140 and electrically connected to the memory controller die 124 through the substrate 140 and interposer 130. Alternatively, the external memory device 126 may be connected to the memory controller die 124 through the processing device 110. In one example, the package device 100 and the external memory device 126 of FIG. 1A may be referred to as an electronic device.

In the example depicted in FIG. 1B, the external memory device 126 is located within the package device 100 and mounted to the interposer 130. In such an example, the external memory device 126 is electrically connected to the memory controller die 124 through the interposer 130. Alternatively, the external memory device 126 may be connected to the memory controller die 124 through the processing device 110. In one example, the package device 100 and the external memory device 126 of FIG. 1B may be referred to as an electronic device.

In the example depicted in FIG. 1C, the external memory device 126 is located external to the package device 100. For example, the external memory device 126 may be mounted to a printed circuit board (PCB) 190, and electrically connected to the memory controller die 124 through the interposer 130 (and/or substrate 140). The external memory device 126 may be connected to the PCB 190 via surface mounting, solder balls or other mounting technique. In the example depicted in FIG. 1C, the external memory device 126 is mounted in a socket 192 disposed on the PCB 190. In one example, the package device 100, the external memory device 126, and the PCB 190 of FIG. 1C may be referred to as an electronic device.

In the example depicted in FIG. 1D, the external memory device 126 is located on the PCB 194. The PCB 194 is external to the package device 100. The PCB 194 is connected to the PCB 190. The external memory device 126 may be mounted to the PCB 194, or another substrate external to the package device 100, and electrically connected to the PCB 190. In one or more examples, the external memory device 126 is connected to the memory controller die 124 through the interposer 130, the substrate 140, the PCB 190, and the PCB 194. The external memory device 126 may be connected to the PCB 194 via surface mounting, solder balls or other mounting technique. In the example depicted in FIG. 1D, the memory controller die 124 is mounted in the socket 192 disposed on the PCB 194. In one example, the package device 100, the external memory device 126, the PCB 190, and the PCB 194 of FIG. 1D may be referred to as an electronic device.

While the above examples with regard to FIGS. 1A-1D describe a single stacked memory device (e.g., memory device 120) included within the package device 100, in other examples, the package device 100 may include more than one stacked memory device. Each of the stacked memory devices may be configured similar to the memory device 120. In other examples, one or more of the stacked memory devices is configured as described above with regard to the memory device 120 and a second one or more of the stacked memory devices is configured differently from the memory device 120. For example, one or more of the memory devices may omit the memory controller die 124, and include a logic die or other type of die. In such an examples, the memory controller die 124 of one of the stacked memory devices may function as the memory controller die 124 of a second one of the stacked memory devices that does not include a memory controller die.

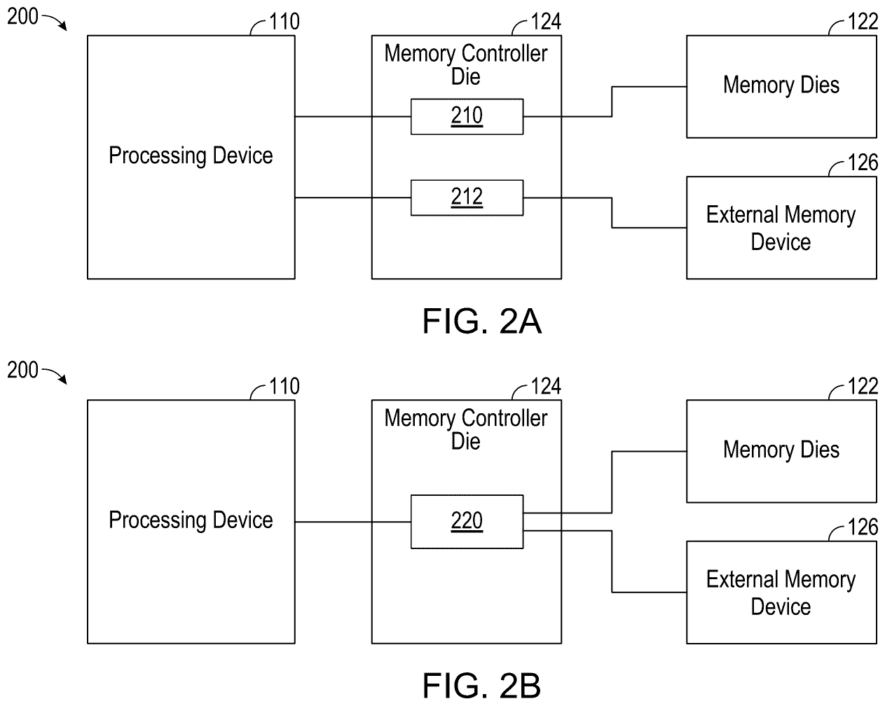

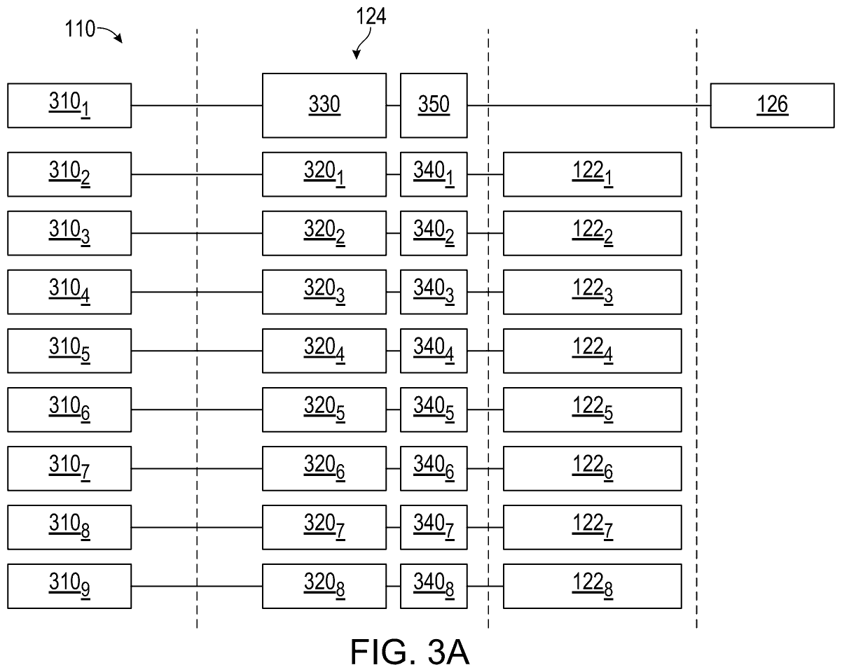

FIG. 2A illustrates a block diagram of an electronic device 200. The electronic device includes at least a portion of the package device of FIG. 1A-FIG. 1D. The processing device 110 is connected to the memory controller die 124. The memory controller die 124 is connected to the memory dies 122 and the external memory device 126. In one example, the processing device 110 is connected to the memory controller die 124 via traces and vias within an interposer (e.g., the interposer 130 of FIG. 1A). The memory controller die 124 is connected to the memory dies 122 via traces and vias within the corresponding stack-up of a memory device (e.g., the memory device 120). The memory controller die 124 is connected to the external memory device 126 via traces and vias within a substrate (e.g., the interposer 130, the substrate 140, and/or the PCB 190 of FIG. 1A-FIG. 1D).

In the example of FIG. 2A, the memory controller die 124 includes interconnect circuitry 210 and interconnect circuitry 212. The interconnect circuitry 210 and the interconnect circuitry 212 are each connected with the processing device 110. For example, the processing device 110 may include first interconnect circuitry connected to the interconnect circuitry 210 and second interconnect circuitry connected to the interconnect circuitry 212. The interconnect circuitry 210 receives command signals and data signals that have the memory dies 122 as a final target (e.g., include an address associated with one or more of the memory dies 122). Accordingly, the interconnect circuitry 210 receives the corresponding memory command and data signals, and controls the communication of the corresponding memory commands and data signals to the corresponding one or more of the memory dies 122. The interconnect circuitry 212 receives command and data signal that have the external memory device 126 as a final target (e.g., include an address associated with the external memory device 126). Accordingly, the interconnect circuitry 212 receives the corresponding memory command signals and data signals, and controls the communication of the corresponding memory command signals and data signals to the external memory device 126. In the example of FIG. 2A, channels between the processing device 110, the memory controller die 124, and the memory dies 122 are separate from the channels between the processing device 110, the memory controller die 124, and the external memory device 126. Stated another way, shared channels are not used to communicate with the memory dies 122 and the external memory device 126.

FIG. 2B illustrates a block diagram of an electronic system 202. The electronic system 202 includes at least a portion of the package device 100 of FIG. 1A-FIG. 1D. The processing device 110 is connected to the memory controller die 124. The memory controller die 124 is connected to the memory dies 122 and the external memory device 126. In one example, the processing device 110 is connected to the memory controller die 124 via traces and vias within an interposer (e.g., the interposer 130 of FIG. 1A). The memory controller die 124 is connected to the memory dies 122 via traces and vias within the corresponding stack up of a memory device (e.g., the memory device 120). The memory controller die 124 is connected to the external memory device 126 via traces and vias within a substrate (e.g., the interposer 130, the substrate 140, the PCB 190, and/or the PCB 194 of FIG. 1A-FIG. 1D).

In the example of FIG. 2B, the memory controller die 124 includes interconnect circuitry 220. The interconnect circuitry 220 is connected with the processing device 110. For example, the processing device 110 may include interconnect circuitry that is connected to the interconnect circuitry 220. The interconnect circuitry 210 receives command signals and data signals that have the memory dies 122 and the external memory device 126 as a final target. Accordingly, the interconnect circuitry 220 determines if the memory dies 122 or the external memory device 126 is the final target of the command signals and data signals (e.g., the memory commands). The interconnect circuitry 220 outputs the memory command signals and the data signals to the memory dies 122 or the external memory device 126 that is determined to be the final target. In one example, the interconnect circuitry 220 includes arbitration circuitry that determines the final target (e.g., the memory dies 122 or the external memory device 126), and controls the communication of the command signals and/or data signals to the final target. In the example of FIG. 2B, one or more channels are used to communicate between the processing device 110, the memory controller die 124, the memory dies 122 and the external memory device 126. Stated another way, one or more channels are shared to communicate with the memory dies 122 and the external memory device 126.

In one or more examples, a memory command (e.g., command signal and data signal) is received by the memory controller die 124 and routed to one or more of the memory dies 122 or to the external memory device 126 based on the address of the memory command. For example, if the address of the memory command is for a memory line (e.g., an address) within one of the memory dies 122, the memory command is routed to the corresponding memory die 122. Further, if the address of the memory command is for a memory line (e.g., an address) within one of the external memory device 126, the memory command is routed to the corresponding memory device 126. With reference to FIG. 2A, the interconnect circuitry 210 receives memory commands having an address associated with the memory dies 122, and communicates the memory commands to the memory dies 122. Further, the interconnect circuitry 212 receives memory commands having an address associated with the external memory device 126, and communicates the memory commands to the external memory device 126. In such an example, the processing device 110 determines if the memory command has an address associated with the memory dies 122 or the external memory device 126, and outputs the memory command to the corresponding one of the interconnect circuitry 210 or the interconnect circuitry 212.

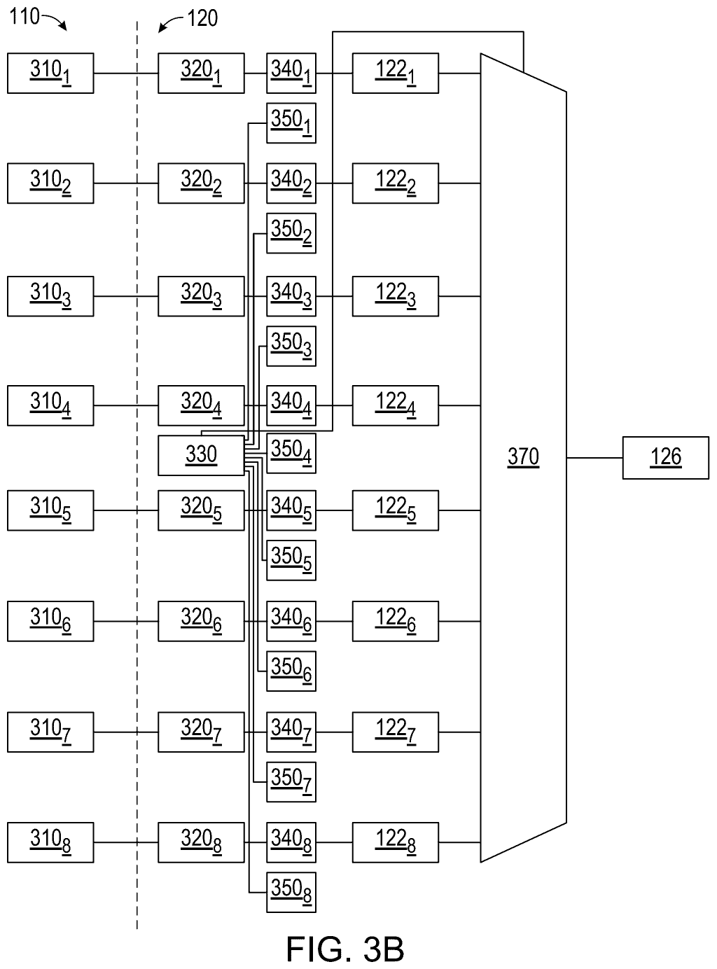

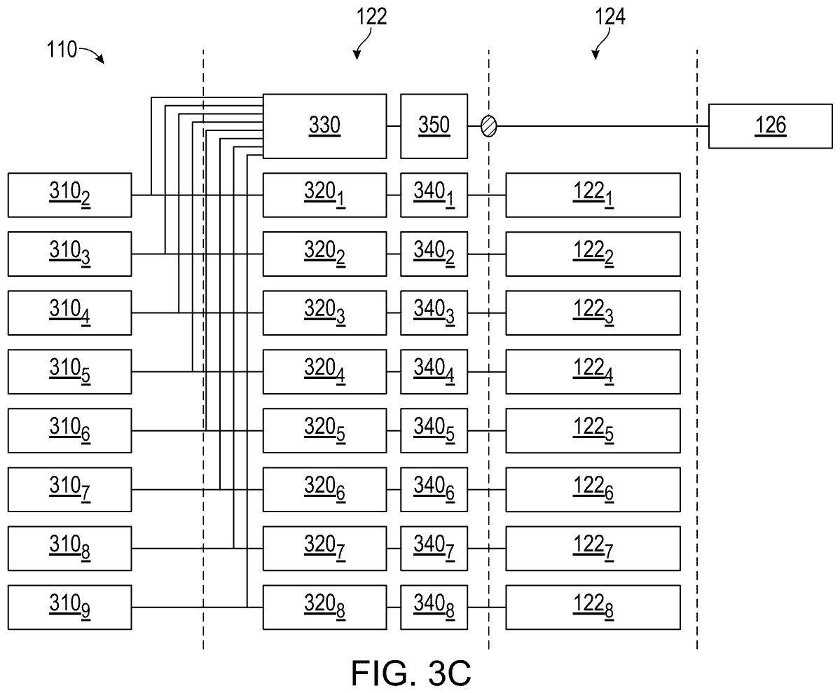

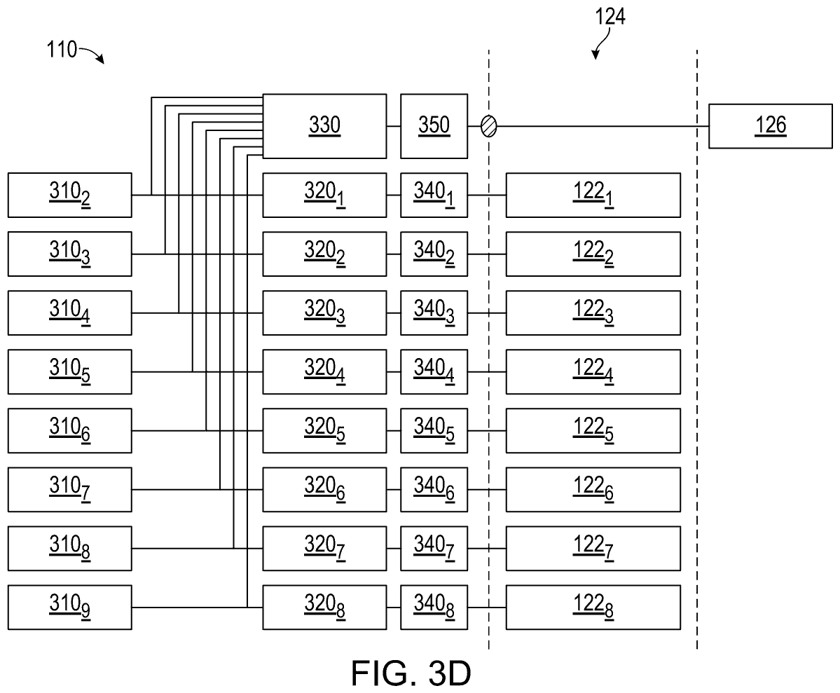

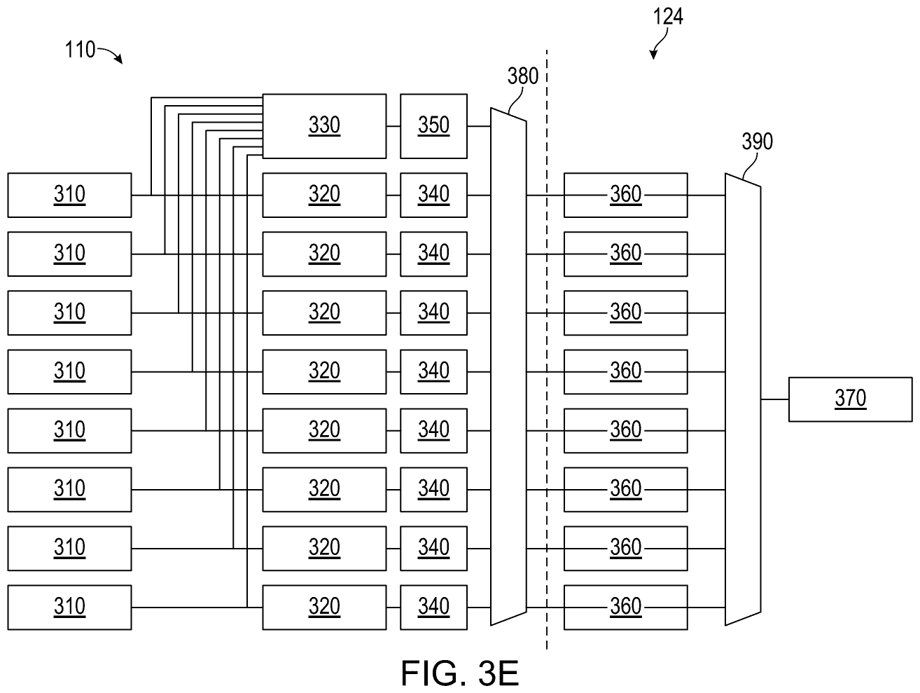

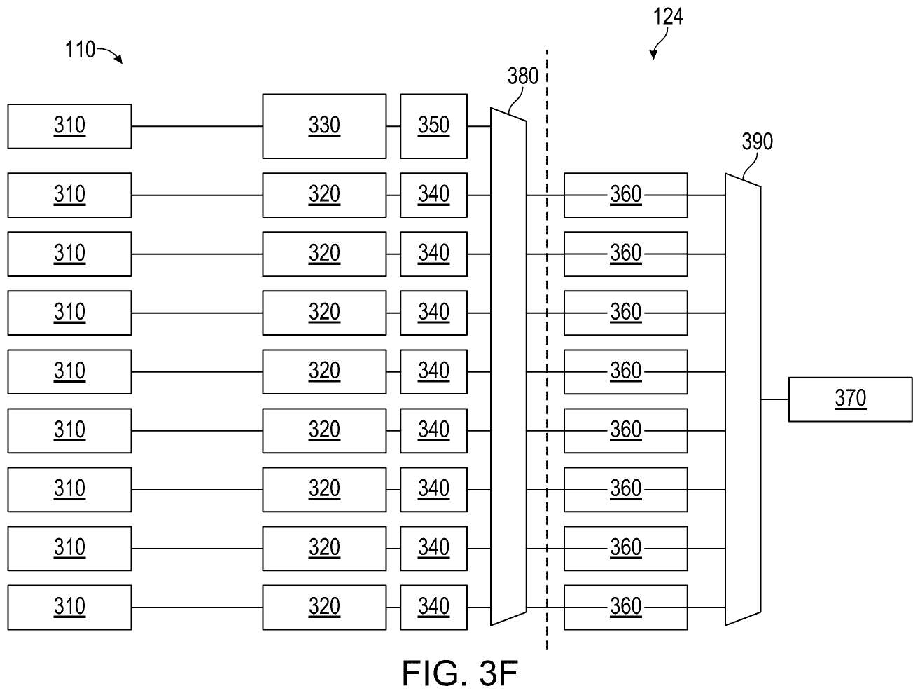

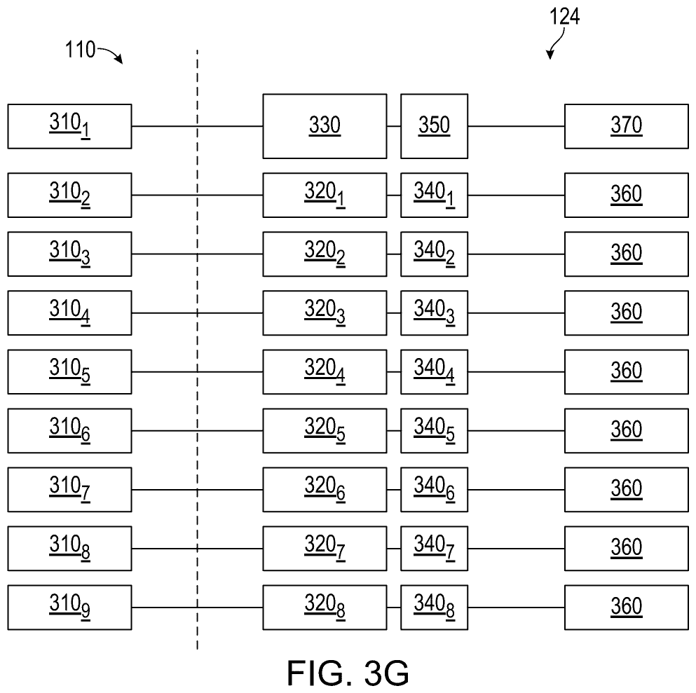

FIG. 3A illustrates an example block diagram of the processing device 110, the memory controller die 124, the memory dies 122, and the external memory device 126. The processing device 110 includes coherency station circuitries 310. The coherency station circuitries 310 are part of the interconnect circuitry of the processing device 110. In one example, the coherency station circuitries 310 are replaced by other types of interconnect circuitry. The coherency station circuitries 310 output memory commands via interconnect circuitry of the processing device 110. The coherency station circuitries 310 manage memory conflicts within the memory dies 122 and/or the external memory device 126.

The coherency station circuitry 310₁ outputs memory commands associated with the external memory device 126. For example, the coherency station circuitry 310₁ is connected to the external memory device 126. In one example, the coherency station circuitry 310₁ is connected to the arbitration circuitry 330 and the memory queue circuitry 350. The arbitration circuitry 330 and the memory queue circuitry 350 may be part of interconnect circuitry (e.g., the interconnect circuitry 212 of FIG. 2A). In one or more examples, one or more of the arbitration circuitry 330 and the memory queue circuitry 350 may be replaced with other types of interconnect circuitry.

The arbitration circuitry 330 and the memory queue circuitry 350 are connected with the external memory device 126. In one example, the arbitration circuitry 330 and the memory queue circuitry 350 are used to write data to and read data from the external memory device 126. In one example, memory commands are loaded within the memory queue circuitry 350. When the arbitration circuitry 330 detects that the memory queue circuitry 350 includes a memory command for the external memory device 126, the memory command is issued to the external memory device 126 from the memory controller die 124.

In one example, the coherency station circuitries 310₂-310₉ are connected to respective ones of the arbitration circuitries 320₁-320₈ and the memory queue circuitries 340₁-340₈. The coherency station circuitries 310₂-310₉ output memory commands to the respective ones of the arbitration circuitries 320₁-320₈ and the memory queue circuitries 340₁-340₈. In one or more examples, one or more of the arbitration circuitry 320 and the memory queue circuitries 340 may be replaced with other types of interconnect circuitry.

The arbitration circuitries 320 and the memory queue circuitries 340 are connected with the memory dies 122₁-122₈. In one example, memory commands are loaded within the memory queue circuitries 340. When the memory arbitration circuitries 320 detect that the memory queue circuitry 340 includes a memory command for an associated one of the memory dies 122, the memory command is issued to the memory die, or dies, 122 from the memory controller die 124. In one example, the memory arbitration circuitries 320 and the memory queue circuitries 340 are used to write data to and read data from the memory dies 122.

In the example of FIG. 3A the channel, or channels, used to communicate between the coherency station circuitry 310₁, the arbitration circuitry 330, the memory queue circuitries 350 and the external memory device 126 differs from the channel, or channels, used to communicate between the coherency station circuitries 310₂-310₉, the arbitration circuities 320, the memory queue circuitries 340, and the memory dies 122.

In one or more examples, a channel is shared between the coherency station circuitries 310, the external memory device 126 and the memory dies 122. For example, one or more of the coherency station circuitries 310 are used to communicate memory commands for the external memory device 126 and one or more of the memory dies 122. In such examples, the routing of memory commands from the processing device 110 to the external memory device 126 and the memory dies 122 is controlled by the arbitration circuitry 320, the arbitration circuitry 330, and/or the selection circuitry 370, 380 and/or 390.

FIG. 3B illustrates a portion of package device 100 of FIG. 1A, 1B, 1C or 1D. For example, FIG. 3B illustrates coherency station circuitry 310 of the processing device 110, arbitration circuitry 320, arbitration circuitry 330, memory queue circuitries 340, memory queue circuitries 350, memory dies 122, selection circuitry 370, and memory device 126. In one example, the arbitration circuitries 320, 330 and the memory queue circuitries 340 and 350, and the selection circuitry 370 are included within the memory controller die 124 of FIGS. 1A-1C. As is illustrated in FIG. 3B, each of the memory queue circuitries 340 is connected to and associated with a respective memory arbitration circuitry 320. In one example, the memory arbitration circuitries 320 and the memory queue circuitries 340 are used to write data to and read data from the memory dies 122. Accordingly, the memory arbitration circuitries 320 and the memory queue circuitries 340 may be referred to as high bandwidth memory arbitration circuitries 320 and high bandwidth memory queue circuitries 340. The memory queue circuitries 350 are connected and associated with the arbitration circuitry 330. In one example, the arbitration circuitry 330 and the memory queue circuitries 350 are used to write data to and read data from the external memory device 126.

In one example, as memory commands for the memory dies 122 are received from the coherency station circuitries 310, the memory queue circuitries 340 are updated with the memory commands. When a memory arbitration circuitry 320 detects that a respective memory queue circuitries 340 includes a memory command for the respective memory die 122, the memory command is issued to the corresponding memory die 122.

In one example, the external memory device 126 shares channels with the memory dies 122. In such examples, channels used to access the memory dies 122 are also used to access the external memory device 126. For example, at least a portion of the wires that make up each of the channels are used to both send and receive data from the memory dies 122 and the external memory device 126. Paths along the channels used to send data to the memory dies 122 and the external memory device 126 are used in reverse to receive data from the memory dies 122 and the external memory device 126. Accordingly, a time multiplexed, or time sliced, process is used to access the memory dies 122 and the external memory device 126. For example, memory commands for the external memory device 126 are received from the coherency station circuitries 310 and stored within the memory queue circuitries 350. Each of the memory dies 122 is associated with a respective one of the memory queues circuitries 350 and corresponding channel. In one example, when a memory command for the external memory device 126 is detected by an arbitration circuitry 330 to be within a memory queue circuitries 350, the corresponding channel is used to communicate with the memory command to the external memory device 126. The arbitration circuitry 330 provides a control signal to the selection circuitry 370 to select the corresponding channel to use to access the external memory device 126. In one example, the arbitration circuitry 330 schedules the memory command during a time slice, or a bit of time, within a respective channel. When a channel is used to access the external memory device 126, the memory die 122 associated with the corresponding channel cannot be accessed during the period in which the channel is used to access the external memory device 126. Accordingly, a time multiplexed based approach is used to communicate on the channels shared between the memory dies 122 and the external memory device 126.

In one example, the arbitration circuitry 330 determines that the memory queue circuitry 350₅ includes a memory command for the external memory device 126. The arbitration circuitry 330 schedules a time period to provide the memory command to the external memory device 126 via the channel associated with the memory die 122₅. Further, the arbitration circuitry 330 provides a control signal to the selection circuitry 370 during the scheduled time period, indicating to the selection circuitry 370 to select the channel associated with the memory die 122₅ to be used to access the external memory device 126 based on the memory command. During the next cycle (e.g., next time period) the channel associated with the memory die 122₅ is used to access the memory die 122₅ based on a memory command within the memory queue circuitries 350₅.

In one example, while a first channel is being used to write to or read from the external memory device 126, one or more other channels may be used to write to or read from a corresponding one or more of the memory dies 122.

In one example, the output of each coherency station circuitry 310 is connected to selection circuitry that determines if a memory command is intended for a memory die 122 or the external memory device 126, and outputs the memory command to a corresponding one of the memory queue circuitries 340 or the memory queue circuitries 350. For example, the selection circuitry determines based on the address of the memory command or another parameter of the memory command if the memory command is intended for a memory die 122 or the external memory device 126 and outputs the memory command to a corresponding one of the memory queue circuitries 340 or the memory queue circuitries 350.

While FIG. 3B illustrates eight coherency station circuitries 310, eight arbitration circuitries 320, eight memory queue circuitries 340, eight memory queue circuitries 350, and eight memory dies 122, in other examples, more or less than eight of each of the above elements may be used. In one example, when the selection circuitry 370 is connected to the channels between each memory die 122 and the external memory device 126, the selection circuitry 370 may be connected such that the selection circuitry 370 is between the memory queue circuitries 340, and the memory queue circuitries 350 and the memory dies 122, or at various other positions along the channels, such that the selection circuitry may be used to control whether the memory dies 122 or the external memory device 126 is accessed via memory commend.

In the example of FIG. 3C, the arbitration circuitry 330 snoops each channel between the coherency station circuitries 310 and the memory queue circuitries 340, and the memory queue circuitries 350 to determine when a memory command for the external memory device 126 is written to memory queue circuitries 350 and to which memory queue circuitries 350 the memory command is written. The arbitration circuitry 330 detects the memory commands intended for the external memory device 126 based on a memory address of the memory command and the external memory device 126. A memory command having a memory address that is associated with the external memory device 126 is detected and routed to the external memory device 126. As is illustrated in FIG. 3C, the arbitration circuitry 330 is connected the channels connected between the coherency station circuitries 310, and the arbitration circuitries 320. Further, a memory queue circuitries 350 is connected to the external memory device 126, and is controlled by the arbitration circuitry 330 to communicate memory commands to the external memory device 126. In the example of FIG. 3C, the arbitration circuitry 320, the arbitration circuitry 330, the memory queue circuitries 340, and the memory queue circuitries 350 are included within the memory controller die 124. The coherency station circuitry 310 is included within the processing device 110.

The example of FIG. 3D is similar to the example of FIG. 3C. In the example of FIG. 3D, the arbitration circuitries 320 and 330 and the memory queue circuitries 340 and 340 are included with the coherency station circuitries 310 within the processing device 110.

In the example of FIG. 3E, the arbitration circuitry 330 is connected to the channels connected between the coherency station circuitries 310, and the arbitration circuitries 320. Further, a memory queue circuitries 340 and 350 are connected to the selection circuitry 380. The output of the switching circuitry is connected to the interconnect circuitry 360, and the selection circuitry 390. The output of the selection circuitry 390 is connected to the selection circuitry 370. The interconnect circuitry 360 is connected to the memory dies 122 of FIGS. 1A-1D. The selection circuitry 370 is connected to the external memory device 126 of FIGS. 1A-1D. In one example, the coherency station circuitry 310, the arbitration circuitry 320, the arbitration circuitry 330, the memory queue circuitries 340, the memory queue circuitries 350, and the selection circuitry 380 are included within the processing device 110, and function as described above to communicate memory commands. The interconnect circuitry 360, selection circuitry 370, and selection circuitry 390 are included within the memory controller die 124, and function as described above to communicate memory commands.

The example of FIG. 3F is configured similar to that of FIG. 3E. In the example of FIG. 3F, the arbitration circuitry 330 is connected with a respective coherency station circuitry 310, and is used to communicate memory commands having a target as the external memory device 126 of FIG. 1A-1D. The selection circuitry 380 outputs a memory command from one or more of the arbitration circuitries 320 and 330 and memory queue circuitries 340 and 350. The output memory commands are received by the interconnect circuitry 360 and/or the selection circuitry 390 based on the target (e.g., the memory dies 122 or the external memory device 126) of the memory command. The interconnect circuitry 360 outputs the memory command, or commands, to the memory dies 122. The selection circuitry 390 outputs the memory command, or commands, to the selection circuitry 370. The memory command, or commands, is output from the selection circuitry 370 to the external memory device 126.

In the example of FIG. 3G, each arbitration circuitry 320 and 330 of the memory controller die 124 is connected to a respective coherency station circuitry 310 of the processing device 110. Further, each arbitration circuitry 320 of the memory controller die 124 is connected to a respective memory queue circuitries 340 of the memory controller die, which is connected to a respective interconnect circuitry 360. The arbitration circuitry 330 of the memory controller die 124 is connected to the memory queue circuitries 350 of the memory controller die 124, which is connected to the respective selection circuitry 370. As is described above, the interconnect circuitries 360 are connected to memory dies 122 and the selection circuitry 370 is connected to the external memory device 126. In the example of FIG. 3F, channels are not shared between the memory dies 122 and the external memory device 126.

With reference to FIGS. 3A-3G, the routing of the memory commands from the processing device 110 to the external memory device 126 or the memory dies 122 is controlled by one or more of the arbitration circuitry 320, the arbitration circuitry 330, and the selection circuitry 370, 380 and/or 390.

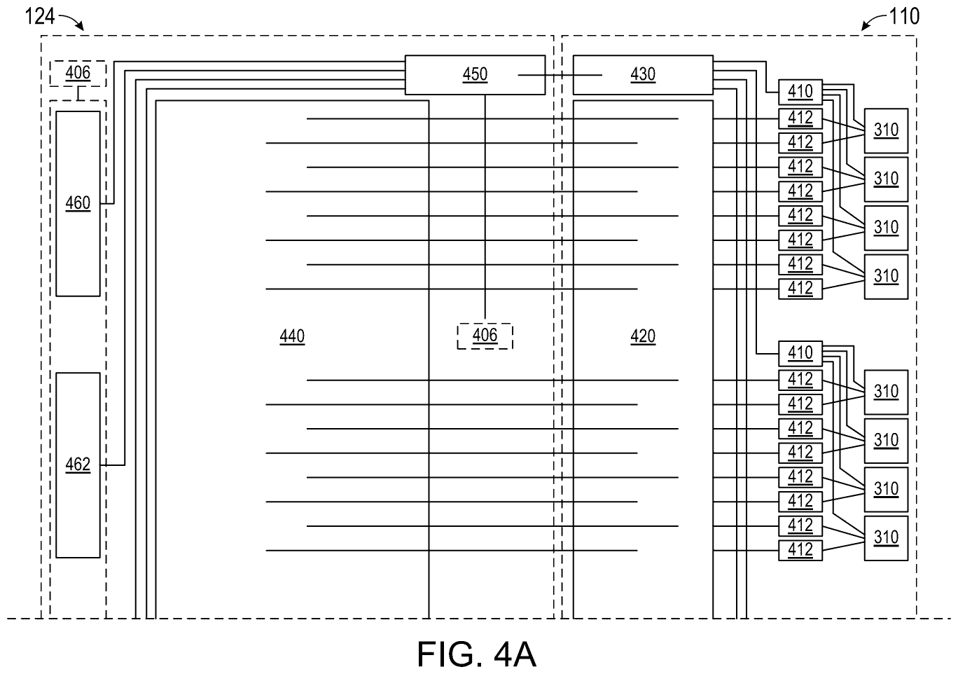

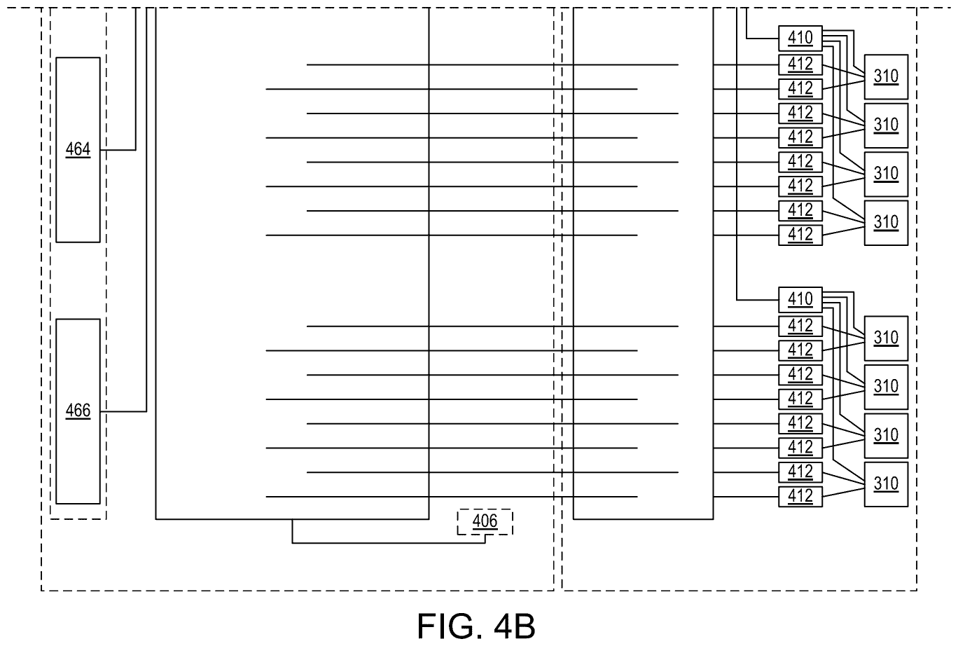

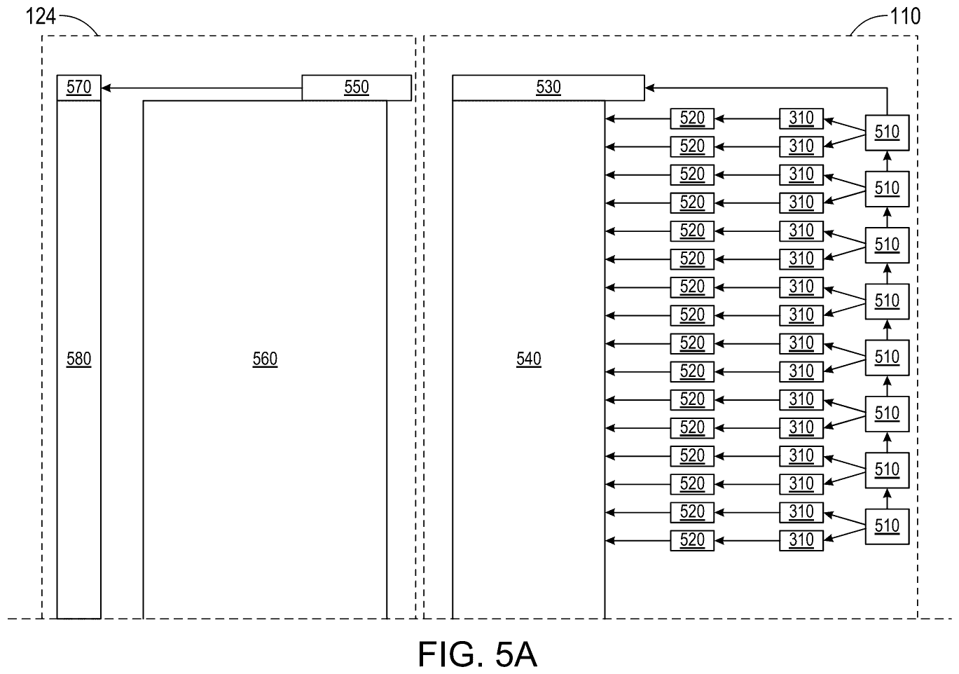

FIG. 4A and FIG. 4B illustrate an example of a portion of the package device 100 of FIG. 1A-FIG. 1D. In FIG. 4A and FIG. 4B, the coherency station circuitry 310 of the processing device 110 is connected to memory controller circuitry 410 and memory controller circuitry 412 of the processing device 110. The memory controller circuitry 412 is connected with interconnect circuitry 420 of the processing device 110. The interconnect circuitry 420 is connected to the interconnect circuitry 440 of the memory controller die 124. The interconnect circuitry 440 is connected to the memory dies 122 (e.g., the memory devices 280). Accordingly, memory commands for the memory the memory dies 122 are communicated along a data path from the coherency station circuitry 310 to the memory controller circuitry 412, to the interconnect circuitry 420, to the interconnect circuitry 440, and to the memory devices 280. In one example, the memory controller circuitry 410 is connected with interconnect circuitry 430 of the processing device 110. The interconnect circuitry 430 is connected to the interconnect circuitry 450 of the memory controller die 124. The interconnect circuitry 450 connected to the interconnect circuitries 440-464, which is connected to the external memory device 126. Accordingly, memory commands for the external memory device 126 are communicated from the coherency station circuitry 310, the memory controller circuitry 410, to the interconnect circuitry 430, to the interconnect circuitry 450, to the interconnect circuitries 440-464, and to the external memory device 126.

Further, one or more processing devices 406 are included within the memory controller die 124. For example, a processing device(s) 406 is connected to the interconnect circuitry 440, 450, and/or 460-466.

The processing device 406 is representative one or more processors such as a microprocessor, a central processing unit, or the like. Further, the processing device 406 may be a combination of different types of types of processors. In examples where the processing device 406 is a microprocessor (or microprocessors), the processing device (or devices) may be any combination of complex instruction set computing (CISC) microprocessor(s), or reduced instruction set computing (RISC) microprocessor(s) among others. In one or more examples, the microprocessor(s) can implement other instruction sets. Further, the processing devices may be a combination of microprocessors implementing a combination of instruction sets. In one or more examples, the processing device 406 is one or more special-purpose processing devices. For the examples, the processing device 406 is a field programmable gate array (FPGA), an application specific integrated circuit (ASIC), a digital signal processor (DSP), an accelerator device, or the like. In one or more examples, the processing device 406 executes instructions stored in a memory to perform the operations described herein.

In the example of FIG. 4A and FIG. 4B, the routing of the memory commands from the processing device 110 to the memory dies 122 and the external memory device 126 is controlled by the interconnect circuitry 440, the interconnect circuitry 450, the interconnect circuitry 460, the interconnect circuitry 462, the interconnect circuitry 464, and/or the interconnect circuitry 466.

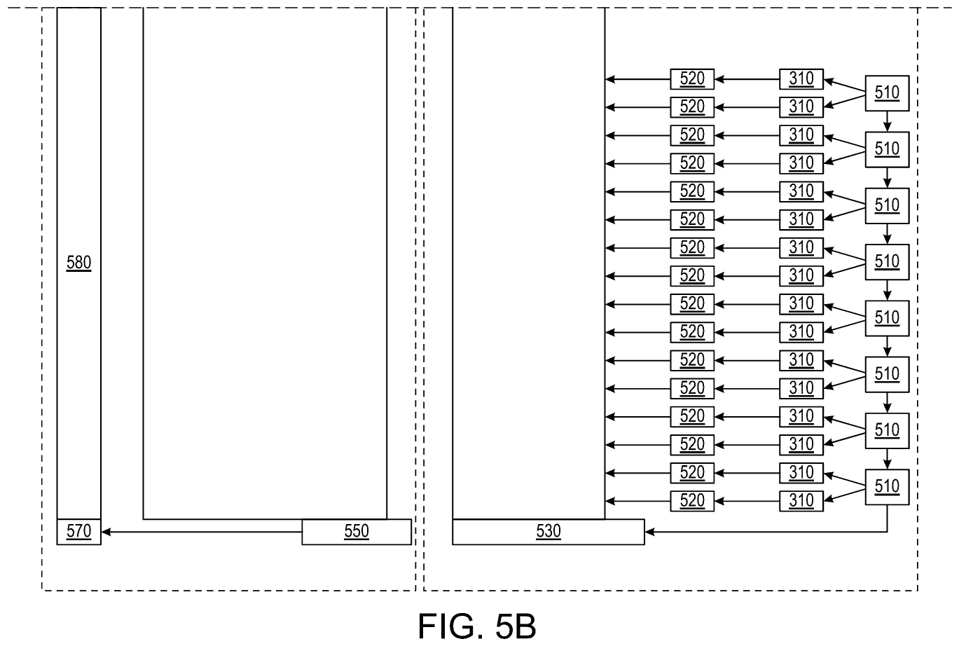

FIG. 5A and FIG. 5B illustrates an example of a portion of the package device 100 of FIG. 1A-FIG. 1D. In FIG. 5A and FIG. 5B, processing device 110 includes transfer control descriptor circuitry 510, coherency station circuitry 310, memory controller circuitry 520, interconnect circuitry 530, and interconnect circuitry 540. The memory controller die 124 includes interconnect circuitries 550-580. The memory controller die 124 is connected to the processing device 110 via the interconnect circuitries 550 and 560 of the memory controller die 124 and the interconnect circuitries 530 and 540 of the processing device 110.

In one example, transfer control descriptor circuitry 510 receives a memory command and determines which of the coherency station circuitries 310 to output the memory command. Each of the coherency station circuitries 310 is connected to a respective memory controller circuitry 520. The transfer control descriptor circuitry 510 determines that a memory command is intended for one or more of the memory dies 122, and outputs a memory command to a respective coherency station circuitry 310 and to a respective memory controller circuitry 520. The memory command is output to the interconnect circuitry 560 via the interconnect circuitry 540. The memory command is output to one or more of the memory dies 122 via the interconnect circuitry 580.

In one example, one or more of the transfer control descriptor circuitries 510 determine that a memory command is intended for the external memory device 126. Accordingly, the memory command is output from the transfer control descriptor circuitries 510 to the interconnect circuitry 530. The memory command is output from the interconnect circuitry 530 to the interconnect circuitry 550 and the interconnect circuitry 570 of the memory controller die 124, and to the external memory device 126 via the interconnect circuitry 570.

In the example of FIG. 5A and FIG. 5B, one or more channels are shared between the memory dies 122 and the external memory device 126. In one or more examples, the routing of memory commands from the processing device 110 to the memory dies 122 and to the external memory device 126 is controlled by the interconnect circuitry 440, the transfer control descriptor circuitry 510, the switching circuitry 512, the selection circuitry 514, the selection circuitry 516, the interconnect circuitry 460, the interconnect circuitry 462, the interconnect circuitry 464, and/or the interconnect circuitry 466.

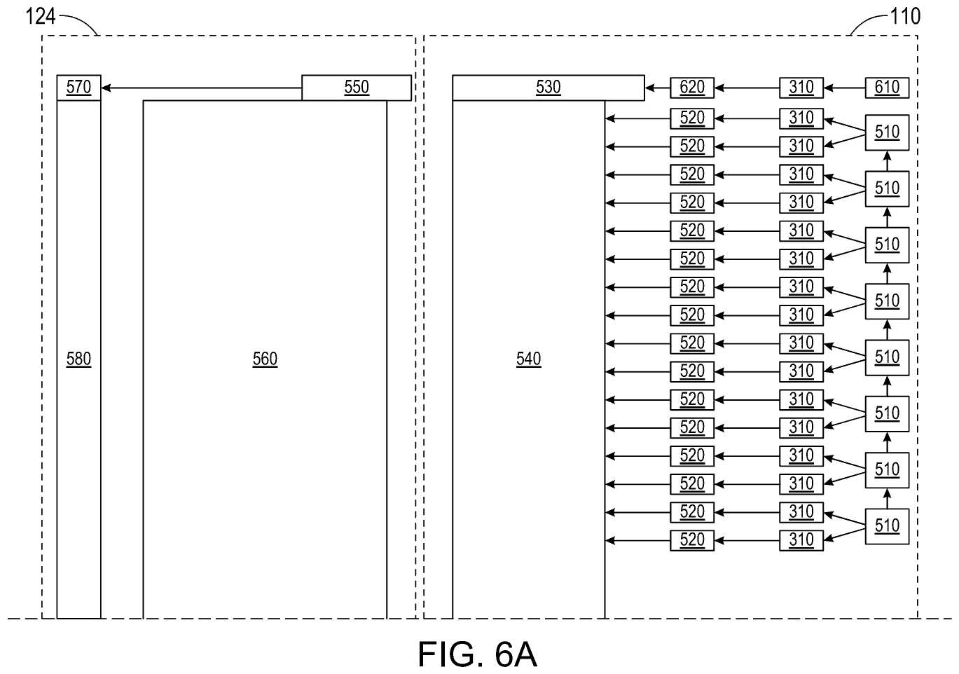

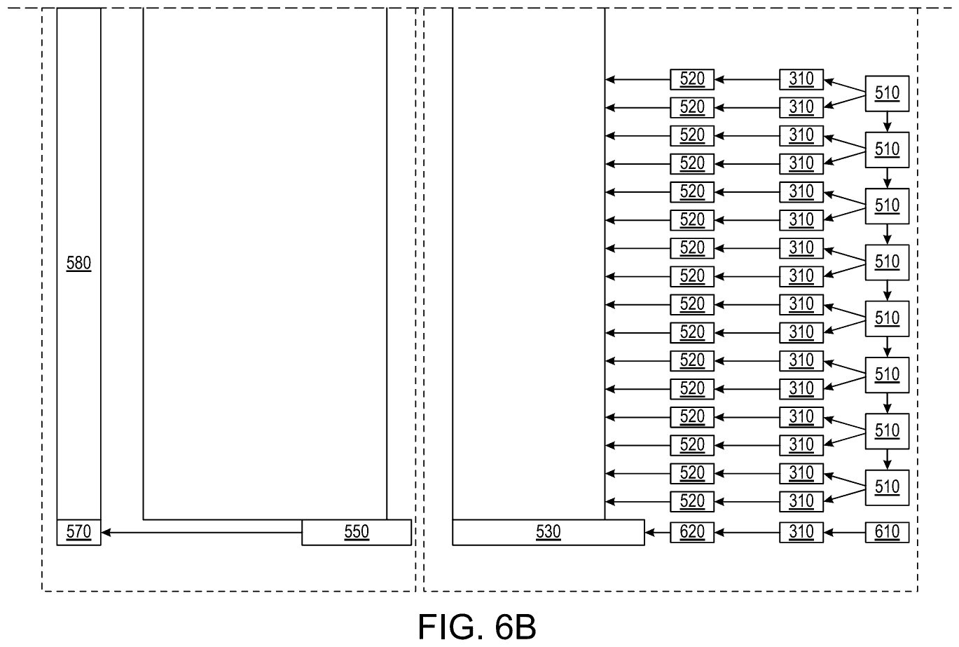

FIG. 6A and FIG. 6B illustrate an example of a portion of the package device 100 of FIG. 1A-FIG. 1D. The example of FIG. 6A and FIG. 6B is similar to that of FIG. 5A and FIG. 5B, however, as compared to the example of FIG. 5A and FIG. 5B, the example of FIG. 6A and FIG. 6B includes transfer control descriptor circuitries 610, coherency station circuitries 310, and memory controller circuitries that are connected to the interconnect circuitry 530. Accordingly, in the example of FIG. 6A and FIG. 6B, channels are not shared and used to communicate with both one or more memory dies 122 and the external memory device 126. Stated another way, the transfer control descriptor circuitries 610 receive memory commands intended for the external memory device 126 and communicate the memory commands via the coherency station circuitries 310, the memory controller circuitries 620, the interconnect circuitry 530, the interconnect circuitry 550 and the interconnect circuitry 570. Further, the transfer control descriptor circuitries 510 receive memory commands intended for the memory dies 122 and communicate the memory commands via the coherency station circuitries 310, the memory controller circuitries 520, the interconnect circuitry 540, the interconnect circuitry 560, and the interconnect circuitry 580.

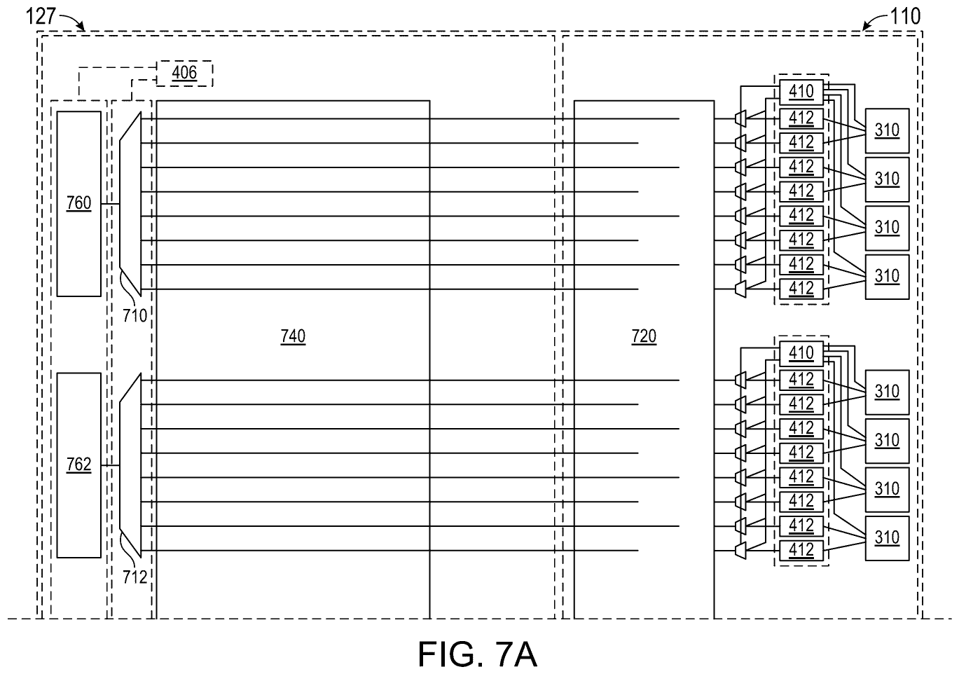

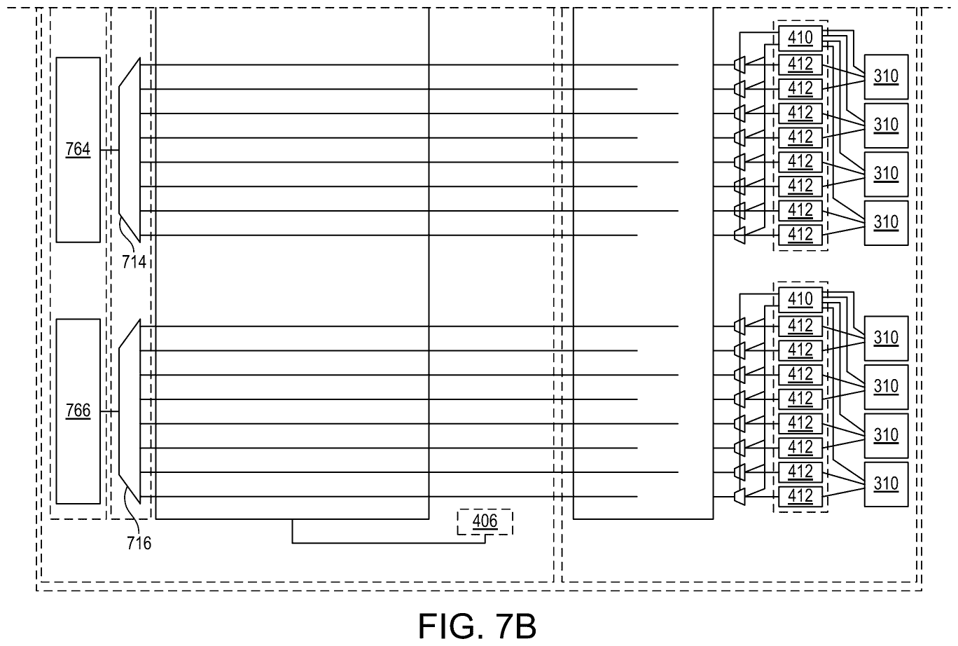

FIG. 7A and FIG. 7B illustrate an example of a portion of the package device 100 of FIG. 1A-FIG. 1D. As compared to the example of FIG. 4A and FIG. 4B, the interconnect circuitries 430 and 440 are omitted. The memory commands for the memory dies 122 and the external memory device 126 flow through the interconnect circuitries 720 and 740. In the example of FIG. 7A and FIG. 7B, the memory controller die 124 includes multiplexers 710-716 (e.g., selection circuitry) that communicates memory commands for one or more external memory devices (e.g., the external memory device 126) from the interconnect circuitry 740 to the interconnect circuitries 760-766, and to the one or more external memory devices. In one or more examples, one or more processing devices 406 are included within the memory controller die 124. For example, a processing device(s) 406 is coupled to the interconnect circuitries 760-766, the interconnect circuitry 750, and/or the multiplexers 710-716.

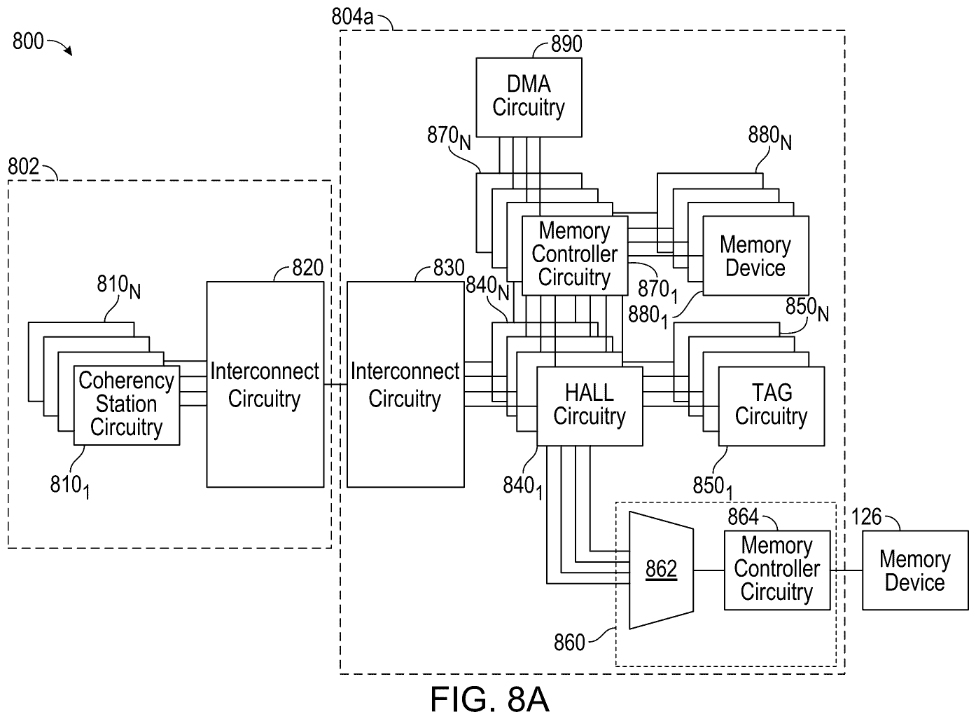

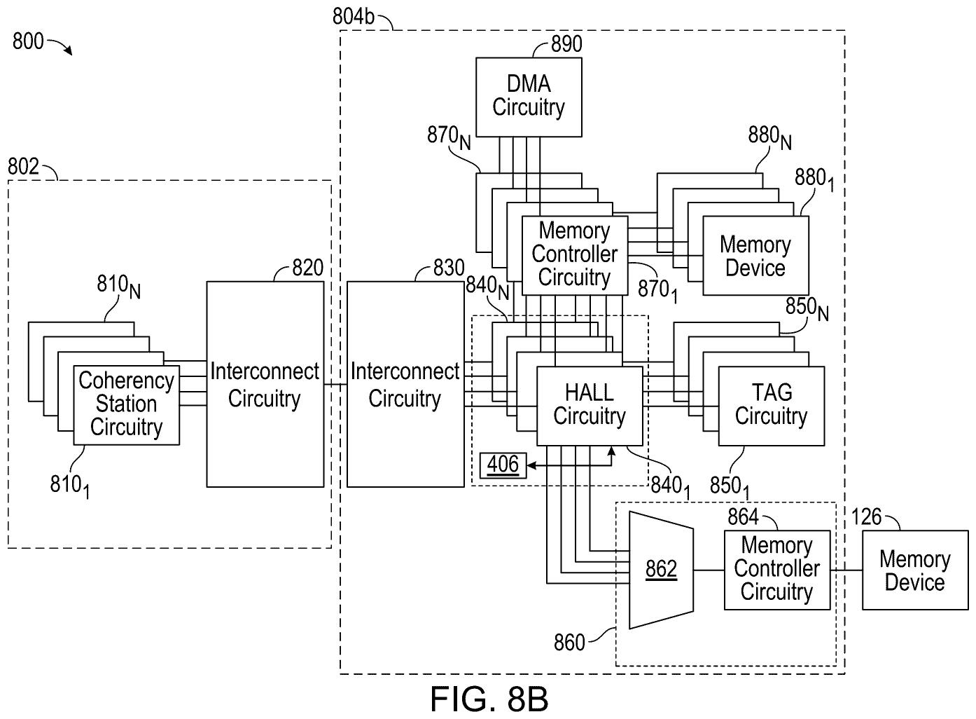

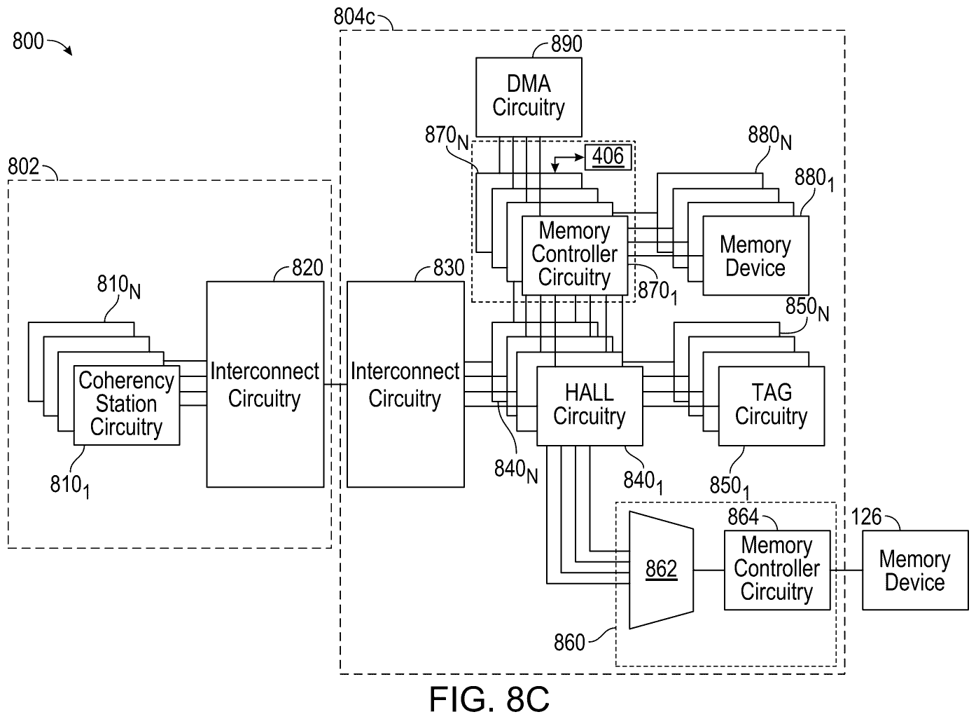

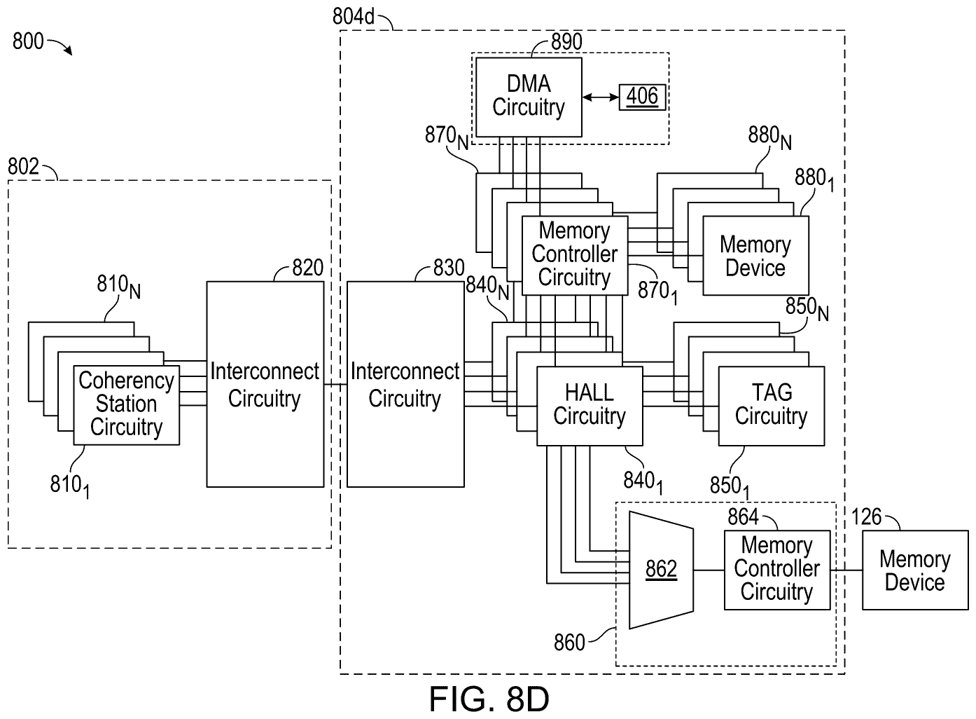

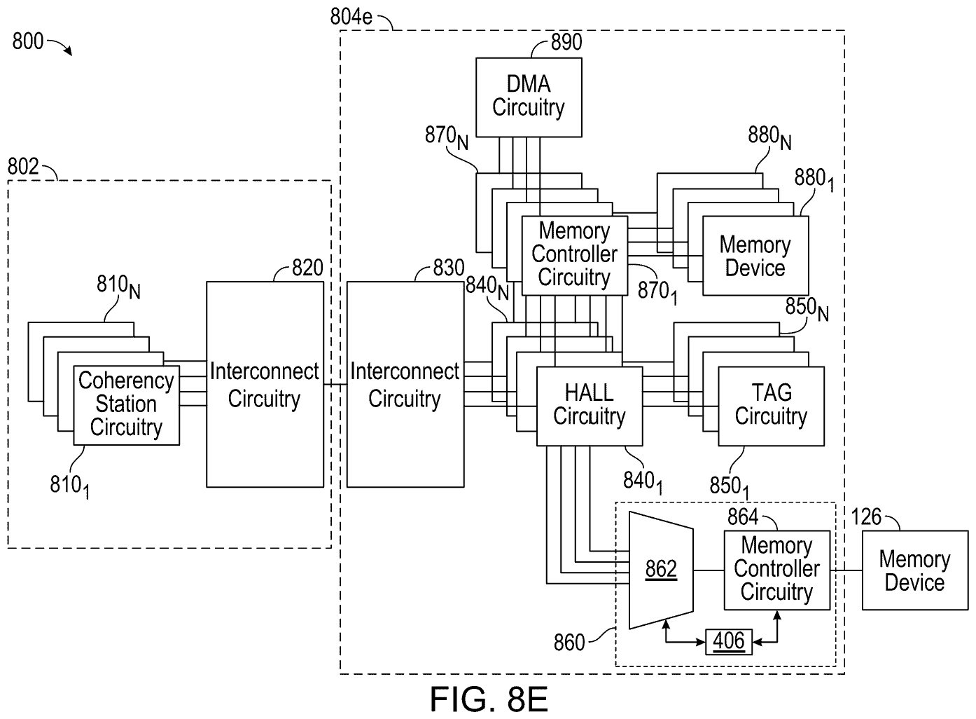

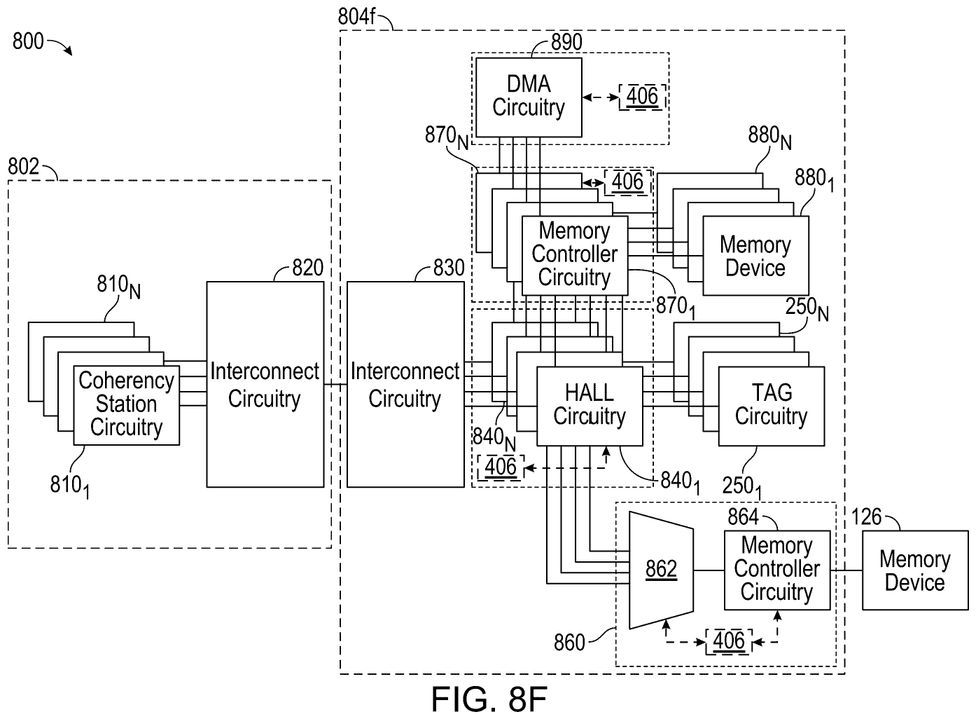

FIG. 8A illustrates an example of a portion of a computing circuitry 800, according to one or more examples. In one example, the computing circuitry 800 resides within the chip package, such as the package device 100 of FIGS. 1A-1C or other similarly adapted chip package. The computing circuitry 800 includes processing circuitry 802 and memory device circuitry 804a. In one example, the processing circuitry 802 is disposed within the processing device 110 of FIGS. 1A-1C. Further, the memory device circuitry 804a corresponds to the memory device 120 of FIGS. 1A-1C. The coherency station circuitry 810 of the processing circuitry 802 outputs memory commands (e.g., read comments and write commands) to the memory device circuitry 804a through the interposer 130 of FIGS. 1A-1C. The coherency station circuitry 810 is configured similar to the coherency station circuitry 310 of FIG. 3A-3F. In one example, the coherency station circuitry 810 outputs memory commands via the interconnect circuitry 820 of the processing circuitry 802 to the interconnect circuitry 830 of the memory device circuitry 804a. In one or more examples, the interconnect circuitry 820 and the interconnect circuitry 830 may be a Universal Chiplet Interconnect Express (UCle) interconnect. In other examples, the interconnect circuitry 820 and 830 corresponds to other interconnect protocols.

The memory device circuitry 804a includes the interconnect circuitry 830, high bandwidth memory attached last level cache (HALL) circuitry 840, tag circuitry 850, memory circuitry 860, memory controller circuitry 870, memory devices 880, and direct memory access (DMA) circuitry 890. In one or more examples, the memory devices 880 reside in the memory dies 122, while some or all of the remaining memory device circuitry 804a resides in the memory controller die 124. In such examples, the memory devices 880 are referred to as HBM devices.

The coherency station circuitry 810 includes coherency station circuitries 810₁-810_{N}, the HALL circuitry 840 includes HALL circuitries 840₁-840_{N}, the tag circuitry 850 includes tag circuitries 850₁-850_{N}, the memory controller circuitry 870 includes memory controller circuitries 870₁-870_{N}, and the memory devices 880 include memory devices 880₁-880_{N}. N is greater than 1. In one example, N is 2, 4, or 8, or more. In one example, each memory device 880 is associated with a respective memory controller circuitry 870, a respective HALL circuitry 840, and a respective tag circuitry 850.

The memory circuitry 860 includes the arbitration circuitry 862, and memory controller circuitry 864. In one example, the memory circuitry 860 includes more than one arbitration circuitry 862 and or more than one memory controller circuitry 864. Further, in one or more examples, more than one external memory device 126 is included and coupled to the memory device circuitry 804a. In one example, the size of the external memory device 126 is greater than that of each and/or the combination of the memory devices 880.

In one example, the memory device circuitry 804a functions as a cache memory for the processing circuitry 802. In such an example, local copies of data stored within the external memory device 126 are stored within the memory devices 880. The tag circuitry 850 maintains tags that associate memory lines and data stored within the memory devices 880 to addresses (e.g., memory lines) within the external memory device 126. In one example, the tag circuitry is a static random access memory (SRAM), or another type of memory. As data within the external memory device 126 is accessed, copies of the data are stored within a memory device 880 via a respective HALL circuitry 840 and a respective memory controller circuitry 870. Further, a tag is updated or created within a respective tag circuitry 850 to associate the address (or memory line(s)) of the data within the memory device 880 to the memory address (memory lines) of the data within the external memory device 126. Accordingly, when future memory commands are used to access the memory address, the memory command is forwarded to the memory devices 880 to retrieve the data. As the memory devices 880 have a higher bandwidth than the external memory device 126, reading data from the memory devices 880 is faster, increasing the operating speed and decreasing lag of the corresponding system (e.g., the package device 100 of FIG. 1A, FIG. 1B, FIG. 1C, or FIG. 1D).

In one example, a read memory command for a first address is provided by the coherency station circuitry 810 and is received by the HALL circuitry 840. The HALL circuitry 840 accesses the tag circuitry 850 to determine if data associated with the first address is stored within in a memory device 880. If a tag within the tag circuitry 850 indicates that the data associated with the first address is stored within a memory device 880, a “hit” is declared and the memory lines of the corresponding memory device 880 is read and the data is output. If a tag within the tag circuitry 850 indicates that the data associated with the first address is not stored within a memory device 880, a “miss” is declared and the read command is provided to the arbitration circuitry 862, and the memory controller circuitry 864 to access to the external memory device 126. The memory line(s) of the external memory device 126 associated with the address of the memory command is accessed, and the corresponding data is output to the processing circuitry 802 via the coherency station circuitry 310. In one example, the data is further stored within one of the memory devices 880, and a corresponding tag within the tag circuitry 850 is updated via the HALL circuitry 840.

For a write command, the coherency station circuitry 810 provides the write command including an address and data to the HALL circuitry 840 via the interconnection circuitries 820 and 830. The HALL circuitry 840 uses the tags within tag circuitry 850 to determine if the address of the write command is within the memory device 880. If the address of the write command is associated with an address (e.g., memory lines) of the memory device 880 (e.g., a “hit”) the data is written to the memory device 880 via the associated address. The data may be written to the corresponding address within the external memory device 126 at a later point, reducing latency in the corresponding system. If the address of the write command is determined to not be associated with an address of the memory device 880 (e.g., a “miss”), the write command is provided to the arbitration circuitry 862, and the memory controller circuitry 864 to be written to the corresponding memory lines of the external memory device 126. In one example, the memory address of the write memory command and corresponding data is additionally loaded into the memory device 880 and a tag within the tag circuitry 850 is updated via the HALL circuitry 840. Accordingly, future access to the requested memory address is sped up as the bandwidth and speed of the memory device 880 is greater than that of the external memory device 126. In one or more examples, instead of directly writing to the external memory device 126, when a miss is determined, the memory line(s) of the external memory device 126 associated with the write command is (are) loaded into the memory device(s) 880 and the tags within the tag circuitry 850 is updated. The data of the write command is written to the corresponding memory lines of the memory device(s). In one example, during a write memory command, the data is written to the memory device 880 and a corresponding tag within the TAG circuitry 850 is updated, and an indication is provided to the external memory device 126, alerting the external memory device 126 to a write to an address within the external memory device 126. The memory controller circuitry 864 and/or the external memory device 126 may prevent a write or read to the same address until the write command is completed by writing the data from the memory device 880 to the external memory device 126.

In one example, the processing circuitry 802 provides one or more memory commands (e.g., read and/or write commands) to the DMA circuitry 890. The memory commands are provided as pre-fetched, predicted, preliminary, pending, or future memory commands. For example, the processing circuitry 802 determines pre-fetched memory commands based on an application executing within the processing circuitry. The pre-fetched memory commands are provided the DMA circuitry 890 before the executed application generates the memory commands. The DMA circuitry 890 and HALL circuitry 840 determines whether or not the addresses and data associated with the predicted memory commands are stored within the memory devices 880 via the tags of the TAG circuitry 850. For addresses that are not found within the memory devices 880, the DMA circuitry 890, the memory controller circuitry 870, and the HALL circuitry 840 provide the corresponding memory commands to the memory controller circuitry 864 and the external memory device 126, to load the corresponding data into memory lines of the memory devices 880. For data that is loaded from the external memory device 126 to the memory devices 880, a corresponding tag within the tag circuitry 850 is updated, mapping the memory lines (e.g., memory addresses) of the memory devices 880 to memory lines (e.g., memory addresses) of the external memory device 126. Accordingly, when the application running on the processing circuitry 802 executes a memory command, the data and address of the memory command is accessible within the memory devices 880, reducing latency and speeding up operation of the corresponding system. In one example, the memory commands provided to the memory controller circuitry 864 and the external memory device 126 are scheduled when bandwidth is available within the memory devices 880, further reducing latency within the corresponding computer system, and increasing the speed of the corresponding computer system.

In one example, the external memory device 126 shares channels between the coherency circuitries 310 with the memory devices 880. Accordingly, the number of wires needed to connect the memory devices 126 and 880 with the coherency station circuitries 810 is reduced, reducing the size, design complexity, and cost of the corresponding semiconductor device.

In one example, each coherency station circuitry 810 is associated with (and configured to access) a respective one of the HALL circuitries 840, the memory controller circuitries 870, and/or the memory devices 880. In another example, each coherency station circuitry 810 is associated with (and configured to access) two or more of the HALL circuitries 840, the memory controller circuitries 870, and/or the memory devices 880.

In one example, a burst (e.g., a plurality) of memory commands is provided to the HALL circuitries 840. The memory commands are provided to the memory controller circuitries 870, which schedule the memory commands with respective ones of the memory devices 880.

In one example, the HALL circuitries 840 and the tag circuitries 850 are included (e.g., reside) within the memory controller die 124. The memory controller circuitries 870 may additionally be included (e.g., reside) within the memory controller die 124. In one example, one or more of the HALL circuitry 840, the tag circuitry 850, the arbitration circuitry 862, the memory controller circuitry 864, the memory controller circuitry 870 and the DMA circuitry 890 is included within the memory controller die 124 of FIGS. 1A-1C. In one example, at least one of the of the HALL circuitry 840, the tag circuitry 850, the arbitration circuitry 862, the memory controller circuitry 864, the memory controller circuitry 870, and the DMA circuitry 890 is external to the memory controller die 124 of FIGS. 1A-1C. For example, the arbitration circuitry 862 and/or the memory controller circuitry 864 are included external to the memory controller die 124 of FIGS. 1A-1C.

In one or more examples, one or more of the HALL circuitry 840, the memory controller circuitry 870, and/or the memory controller circuitry 864 control the routing of the memory command based on the address of the memory command.

In FIG. 8B, the memory device circuitry 804b is configured similar the memory device circuitry 804a of FIG. 8A. As compared to the memory device circuitry 804a, the memory device circuitry includes the processing device 406 coupled to or included within the HALL circuitry 840.

In one example, the processing device(s) 406 performs transformations on data as the data is moved along the data paths between the elements of the memory device circuitry 804a. The transformations include applying one or more scaling factors to the data, applying one or more normalization techniques to the data, and/or transposing the data, among others. In one example, a processing device (or processing devices) 406 is used to control the pre-fetch process described above to load pre-fetched memory lines from the external memory device 126 to the memory devices 880.

In FIG. 8C, the memory device circuitry 804c is configured similar to the memory device circuitry 804a of FIG. 8A. As compared to the memory device circuitry 804a, the memory device circuitry 804c includes one or more processing devices 406 coupled to or included within the memory controller circuitry 870.

In FIG. 8D, the memory device circuitry 804d is configured similar to the memory device circuitry 804a of FIG. 8A. As compared to the memory device circuitry 804a, the memory device circuitry 804d includes one or more processing devices 406 coupled to or included within the DMA circuitry 890. In FIG. 8E, the memory device circuitry 804e is configured similar to the memory device circuitry 804a of FIG. 8A. As compared to the memory device circuitry 804a, the memory device circuitry 804 includes one or more processing devices 406 coupled to or included within the arbitration circuitry 862 and/or the memory controller circuitry 864. In FIG. 8F, the memory device circuitry 804f is configured similar to the memory device circuitry 804a of FIG. 8A. As compared to the memory device circuitry 804a, the memory device circuitry 804f includes one or more processing devices 406 coupled to or included within one or more of the HALL circuitry 840, the memory controller circuitry 870, the arbitration circuitry 862, and/or the memory controller circuitry 864. In one or more examples, one or more processing device(s) 406 is disposed within the data paths connected to the memory devices 880 and/or the external memory device 126. FIGS. 8B-8F illustrate examples of such a configuration. In one or more examples, a processing device or devices 406 may be disposed in a location along a data path that is not illustrated in FIGS. 8B-8F. Such processing devices 406 perform the operations as described above on the data flowing within the data paths.

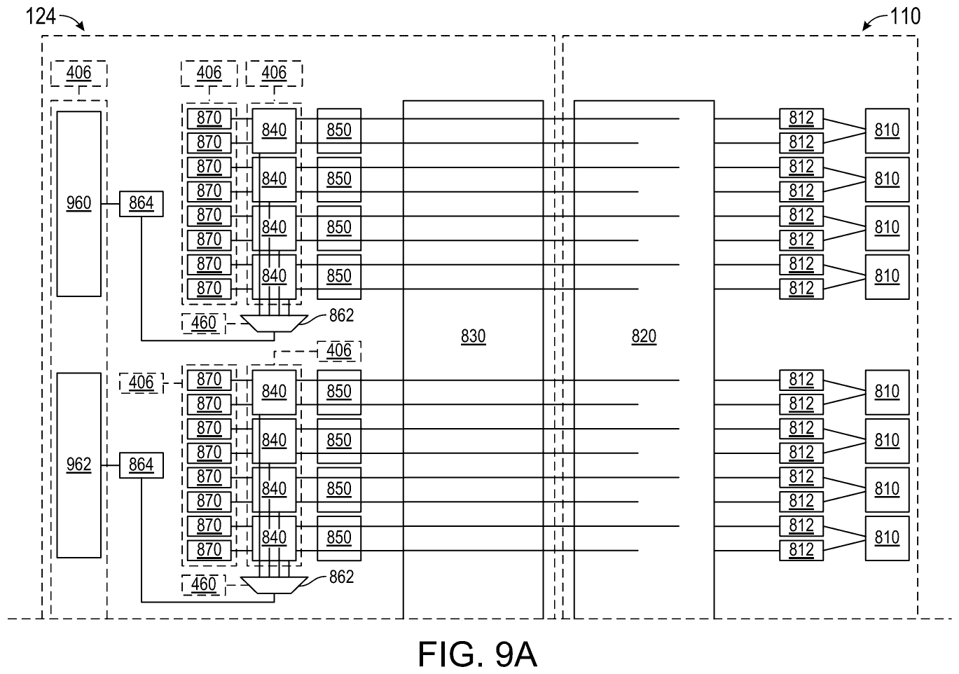

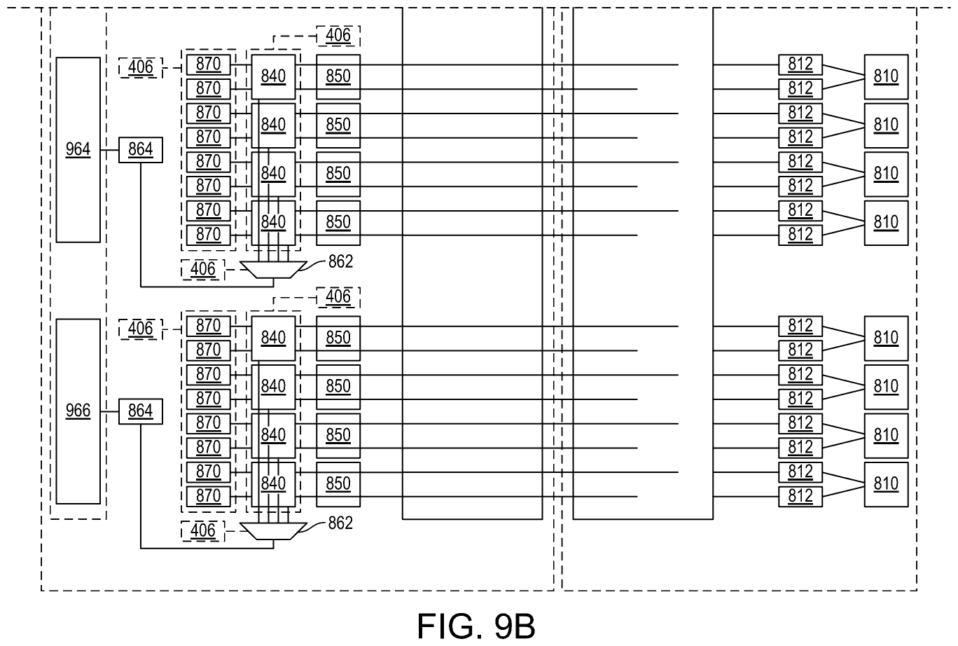

In the example of FIG. 9A and FIG. 9B, the memory controller die 124 is configured similar to that of the examples of FIGS. 8A-8F. The processing device 110 of FIG. 9A and FIG. 9B includes the coherency station circuitry 810, memory controller circuitry 812, and the interconnect circuitry 820. The memory controller circuitry 812 is connected with interconnect circuitry 820 of the processing device 110. The interconnect circuitry 820 is connected to the interconnect circuitry 830 of the memory controller die 124. The memory controller die 124 includes the interconnect circuitry 830, the HALL circuitry 840, the TAG circuitry 850, the arbitration circuitry 862, the memory controller circuitry 864, and the interconnect circuitry 960-966. The interconnect circuitry 960-966 is connected to the external memory device 126. Accordingly, memory commands for the external memory device 126 are communicated along a data path from the coherency station circuitry 810 to the memory controller circuitry 812, to the interconnect circuitry 820, to the interconnect circuitry 830, and to the external memory device 126. In one or more examples, the memory commands for the external memory device 126 are communicated from the coherency station circuitry 810, to the memory controller circuitry 812, to the interconnect circuitry 820, to the interconnect circuitry 830, and to the external memory device 126 via the arbitration circuitry 862 and the memory controller circuitry 864.

In the example of FIG. 9A and FIG. 9B, the memory controller die 124 includes one or more processing devices 406 that are included within or coupled to the interconnect circuitries 860-866, the memory circuitry 860, the HALL circuitry 840, and/or the arbitration circuitry 862. The example of FIG. 9A and FIG. 9B operates similar to as described above with regard to the example of FIGS. 8A-8F. In the example of FIG. 9A and FIG. 9B, the routing of the memory commands is controlled by the interconnect circuitry 830, the HALL circuitry 840, the memory controller circuitry 870, the arbitration circuitry 862, and the interconnect circuitries 960-966.

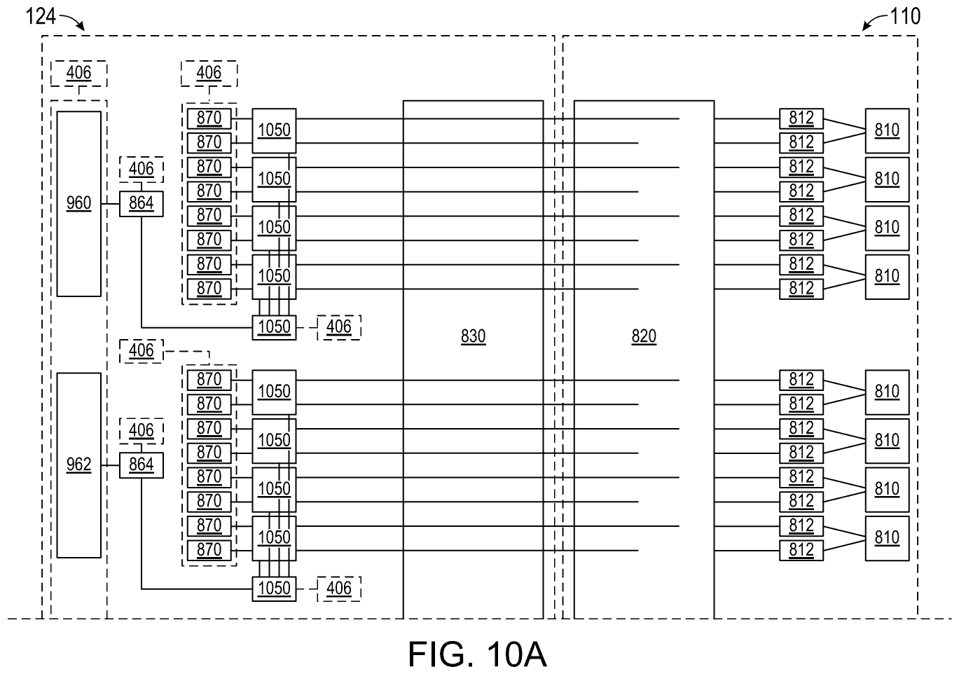

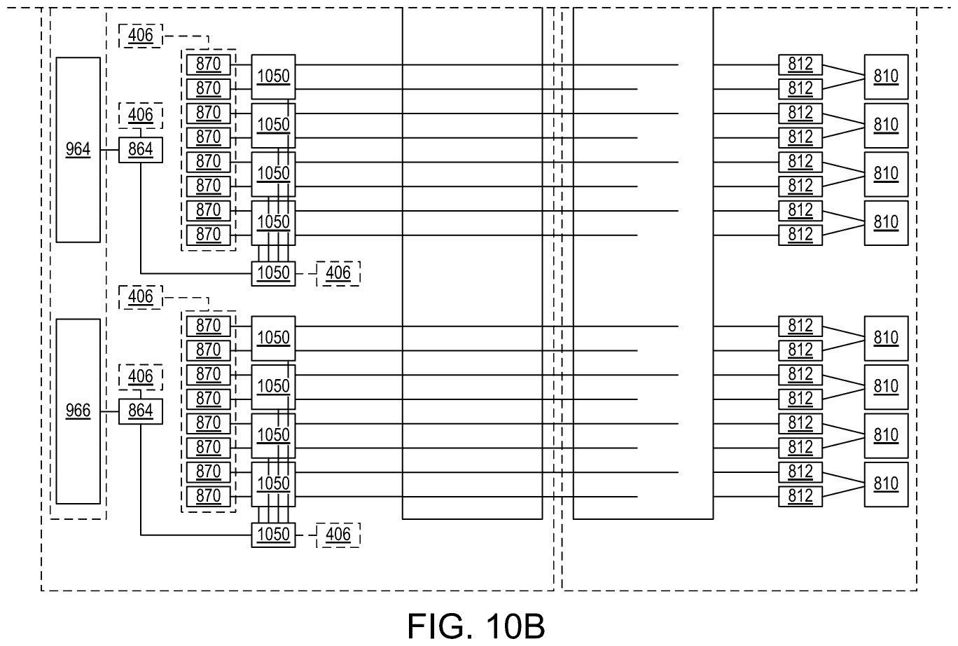

In the example of FIG. 10A and FIG. 10B, the memory controller die 124 includes switching circuitries 1050 that control the communication between the memory controller circuitries 870 and 864, and the interconnect circuitry 830. In one example, a processing device(s) 406 is coupled to or included within the switching circuitry 1050, the memory controller circuitry 870, the memory controller circuitry 864, and/or the interconnect circuitry 960-966. In one example, the switching circuitry 1050 determines whether a memory command is to be forwarded to the memory controller circuitry 870 and to the memory devices 880 or to the memory controller circuitry 864 and the external memory device 126 based on a memory address of the memory command. In one example, the switching circuitry 1050 receives a memory command and determines that the memory command is intended for the memory devices 880 based on the address of the memory command (e.g., the address of the memory command is associated with the memory devices 880). Accordingly, the switching circuitry 1050 outputs the memory command to the memory controller circuitry 270 for the memory devices 880. In another example, the switching circuitry 1050 receives a memory command and determines that the memory command is intended for the external memory device 126 based on the address of the memory command (e.g., the address of the memory command is associated with the external memory device 126). Accordingly, the switching circuitry 1050 outputs the memory command to the memory controller circuitry 864 for the external memory device 126. In one example, the routing is controlled by the interconnect circuitry 830, the memory controller circuitry 870, the switching circuitry 1050, and the interconnect circuitries 960-966.

As is described in the above, a memory controller die within a memory die stack is used to provide memory commands to memory dies of the memory die stack and to an external memory device (e.g., a memory device external to the memory die stack). In one example, the memory die stack is included within a package device with a processing device. The processing device outputs memory commands to the memory controller die, and the memory controller die outputs the memory command to a memory die within a corresponding memory die stack or the external memory device. In one example, the memory commands are communicated along channels from the processing device and to the stacked memory dies and the external memory. The channels may independent, not shared, such that different channels are used to communicate with the stacked memory dies and the external memory. In another example, one or more of the channels are shared. In an example where there are one or more shared channels, the one or more channels are used to communicate memory commands to the stacked memory dies and to the external memory device. In one or more examples, the stacked memory dies may be used as a cache memory for the external memory device. In such an example, the memory controller die controls the stacked memory dies to function as a cache memory for the external memory device based on the memory commands received from a processing device.

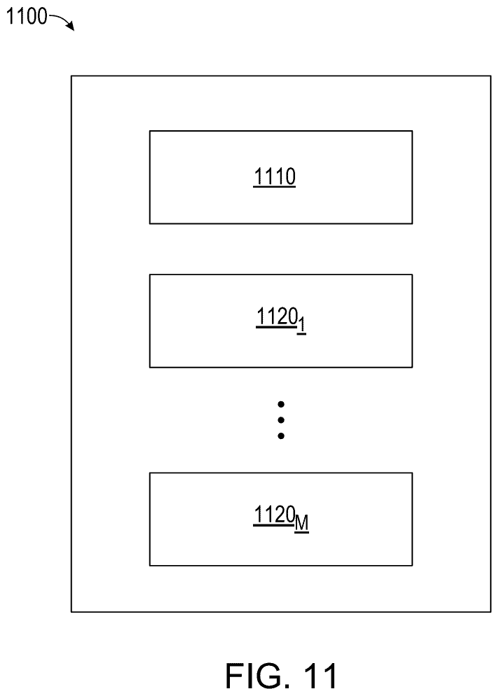

FIG. 11 illustrates a block diagram of a computer system 1100. The computer system 1100 includes processing device 1110 and one or more electronic devices 1120. The processing device 1110 is a CPU or a GPU, among others. In one example, the computer system 1100 includes one or more processing devices 1110. The processing device 1110 is connected to the electronic device or devices 1120. In one example, the computer system 1100 includes a single electronic device 1120. In another example, the computer system 1100 includes two or more electronic devices 1120₁-1120_{M}. M is two or more.

The electronic device 1120 is configured similar to a package device as is described above with regard to FIGS. 1A-10. The electronic device 1120 may have any of the configurations or combination of configurations as is described above with regard to FIGS. 1A-1D. In one example, each of the electronic devices 1120 is configured similarly. In one or more examples, two or more of the electronic devices 1120 has a different configuration. The electronic device 1120 may function as an accelerator device for the processing device 1110. For example, the electronic device 1120 performs one or more functions based on instructions provided by the processing device 1110 to complete a corresponding operation or operations. In an example where more than one electronic device 1120 is included, each electronic device 1120 may perform a function or functions for a similar operation or for different operations.

In one example, the computer system 1100 is part of a distributed computer system. In such an example, the computer system 1100 is a server computer system. In such an example, the distributed computer system includes multiple computer systems that are configured similar to the computer system 1100. In one or more examples, each of the computer systems are connected via a network (wireless or wired connections), and each of the computer systems include network interconnect circuitry that is used communicate with each other.

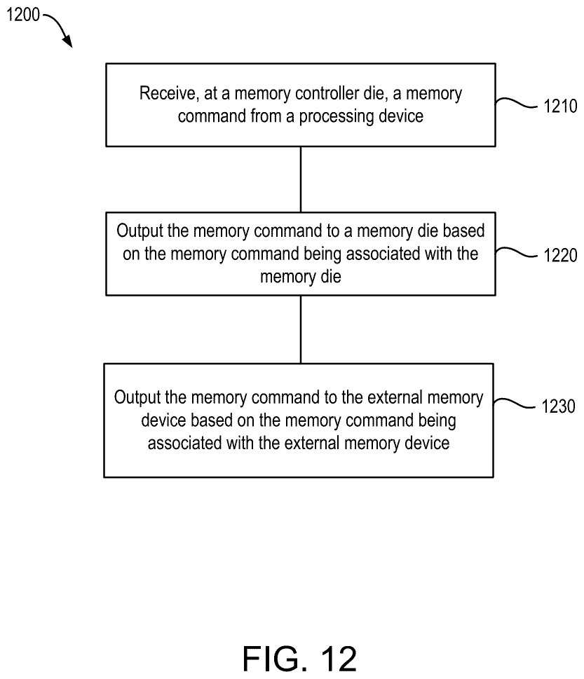

FIG. 12 illustrates a flowchart of a method 1200 for operating a memory controller die (e.g., the memory controller die 124 of any of the above-described figures). At 1210 of the method 1200, a memory controller die receives a memory command from a processing device. For example, with regard to FIGS. 1A-1D, the memory controller die 124 receives a memory command from the processing device 110. In one example, the memory command is a read command or a write command. The memory command includes a target address. The target address is associated with a memory die 122 and/or the external memory device 126.

At 1220 of the method 1200, the memory command is output to a memory die based on the memory command being associated with the memory die. In one example, the memory controller die 124 outputs the memory command to one of the memory dies 122 based on the memory command having a target address associated with one of the memory dies 122. In one example, the memory controller die 124 determines that the memory address of the memory command is a memory address associated with one or more of the memory dies 122, and outputs the memory command to the memory dies 122. The memory controller die 124 determines which of the memory dies 122 has the memory address of the memory command, and outputs the memory command to that memory die 122. In one or more examples, the memory controller die 124 forwards the memory command to the memory dies 122 without determining that the memory command has a target address associated with one or more of the memory dies 122. For example, the processing device 110 outputs the memory command with an indication that the intended target is one or more of the memory dies 122. In another example, the memory controller die 124 includes first circuitry (e.g., arbitration circuitries and/or memory queue circuitries, among others) associated with the memory dies 122 and second circuitry associated with the external memory device 126. The processing device 110 outputs memory commands associated with the memory dies 122 to the first circuitry. The memory controller die 124 receives the memory command at the first circuitry. The memory controller die 124 outputs the memory command from the first circuitry to the memory dies 122. In one example, the memory controller die 124 outputs the memory command from the first circuitry to one of the memory dies 122 based on where in the first circuitry the memory command is received. For example, each memory die 122 is associated with different circuitry elements (e.g., different arbitration circuitry and/or memory queue circuitry) of the first circuitry. The memory controller die 124 outputs the memory command to a one of the memory dies 122 based on which circuit elements receives the memory command.

The memory controller die 124 communicates data from the one or more memory dies 122 via the same path used to communicate the memory command to the one or memory dies 122. For example, data may be transferred from one or more of the memory dies 122 to the memory controller die 124 and from the memory controller die 124 to the processing device 110.

At 1230 of the method 1200, the memory command is output to the external memory device based on the memory command having a target address associated with the external memory device. In one example, the memory controller die 124 outputs the memory command to the external memory device 126 based on the memory command having a target address associated with the external memory device 126. In one example, the memory controller die 124 determines that the memory address of the memory command is associated with the external memory device 126, and outputs the memory command to the external memory device 126. In one or more examples, the memory controller die 124 forwards the memory command to the external memory device 126 without determining that the memory command has a target address associated with the external memory device 126. For example, the processing device 110 outputs the memory command with an indication that the intended target is the external memory device 126. In another example, the memory controller die 124 includes first circuitry (e.g., arbitration circuitries and/or memory queue circuitries, among others) associated with the memory dies 122 and second circuitry associated with the external memory device 126. The processing device 110 outputs memory commands associated with the memory dies 122 to the second circuitry. The memory controller die 124 receives the memory command at the second circuitry. The memory controller die 124 outputs the memory command from the second circuitry to the external memory device 126.

The memory controller die 124 communicates data from the external memory device 126 via the same path used to communicate the memory command to the external memory device 126. For example, data may be transferred from the external memory device 126 to the memory controller die 124 and from the memory controller die 124 to the processing device 110.

In one example, 1210 and 1220 of the method 1200 occur in any order. For example, 1210 may occur before or after 1220 when performing the method 1200. In one example, 1220 and 1230 of the method 1200 occur during at least partially overlapping periods.

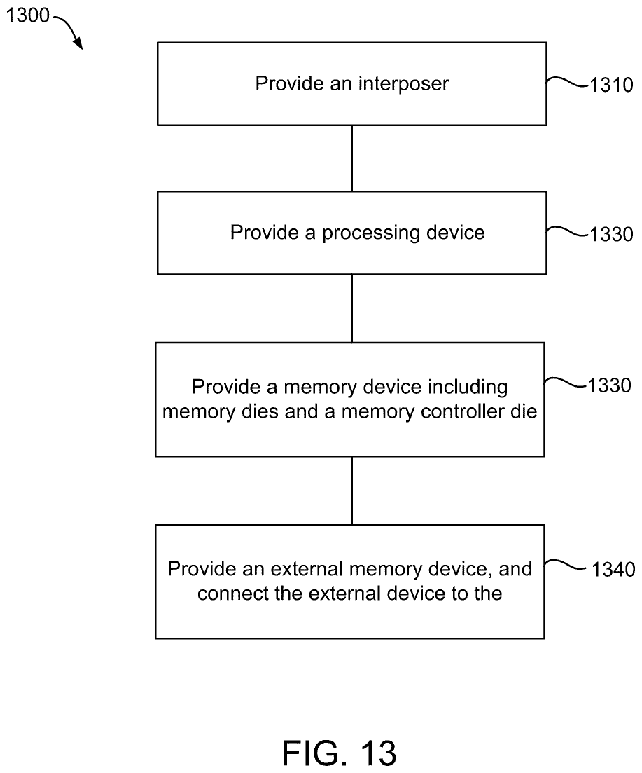

FIG. 13 illustrates a flowchart of a method 1300 for forming an IC device, according to one or more examples. At 1310 of the method 1300, an interposer is provided. For example, with reference to FIG. 1A-FIG. 1D, the interposer 130 is provided. At 1320 of the method 1300, a processing device is provided. For example, with reference to FIG. 1A-FIG. 1D, the processing device 110 is provided. The processing device 110 is mounted to the interposer 130. The processing device 110 is electrically connected and physically connected to the interposer 130.

At 1330 of the method 1300, a memory device including memory dies and a memory controller die is provided. For example, with reference to FIG. 1A-FIG. 1D, the memory device 120 including the memory dies 122 and the memory controller die 124 is provided. The memory device 120 is mounted to the interposer 130. The memory device 120 is electrically connected and physically connected to the interposer 130. The memory device 120 is connected to the processing device 110 via traces and/or vias within the interposer 130. For example, the memory controller die 124 is connected (electrically connected) to the processing device 110 via traces and/or vias within the interposer 130.

At 1340, an external memory device is provided, and the external memory device is connected to the memory controller die. For example with reference to FIG. 1A-1D, the external memory device 126 is provided and is connected with the memory controller die 124. With reference to FIG. 1A, the package substrate 140 is provided and the external memory device 126 is physically connected and electrically connected to the package substrate 140. The package substrate 140 is physically connected and electrically connected to the interposer 130. With reference to FIG. 1B, the external memory device 126 is physically connected and electrically connected to the interposer 130. With reference to FIG. 1C, the PCB 190 is provided and the external memory device 126 is physically connected and electrically connected to the PCB 190. The PCB 190 is physically connected and electrically connected to the interposer 130. In one example, the PCB 190 is physically connected and electrically connected to the interposer 130 via the package substrate 140. With reference to FIG. 1D, the PCB 190 and the PCB 194 are provided and the external memory device 126 is physically connected and electrically connected to the PCB 194. The PCB 194 is physically connected and electrically connected to the PCB 194.

While the foregoing is directed to specific examples, other and further examples may be devised without departing from the basic scope thereof, and the scope thereof is determined by the claims that follow.

What is claimed is:

1. A package device comprising:
a processing device;
memory dies; and
a memory controller die coupled to the processing device and the memory dies, wherein the memory controller die is configured to control communication from the processing device to the memory dies and to an external memory device, wherein the external memory device is external to the memory dies.

2. The package device of claim 1, wherein the memory dies are vertically stacked on the memory controller die.

3. The package device of claim 1, wherein the memory dies and the memory controller die are part of a high bandwidth memory device.

4. The package device of claim 1, wherein the memory dies are a first type of memory and the external memory device is a second type of memory different from the first type.

5. The package device of claim 1, wherein the memory controller die comprises one or more processing devices configured to alter data received from the memory dies or the external memory device.

6. The package device of claim 1 further comprising an interposer, wherein the external memory device and the memory controller die are disposed on the interposer, and wherein the memory dies are disposed on the memory controller die.

7. The package device of claim 1 further comprising an interposer and a substrate, wherein the memory controller die is disposed on the interposer, and the external memory device is disposed on the substrate, wherein the interposer is mounted to the substrate, and wherein the memory dies are disposed on the memory controller die.

8. The package device of claim 1 further comprising an interposer and a substrate, wherein the memory controller die is disposed on the interposer, and wherein the interposer is disposed on the substrate and the substrate is connected to a printed circuit board, wherein the external memory device is disposed on the printed circuit board.

9. The package device of claim 1, wherein the memory controller die comprises control circuitry configured to:
receive a memory command associated a memory line; and
output the memory command to one of the memory dies or the external memory device based on a determination of a location of the memory line.

10. The package device of claim 9 wherein the memory dies are configured to store a copy of data stored within the external memory device.

11. The package device of claim 9, wherein the memory controller die further comprises tag circuitry configured to store tags that associate memory lines of the memory dies with memory lines of the external memory device.

12. The package device of claim 11, wherein the memory controller die further comprises direct memory access circuitry configured to control the control circuitry to load a first plurality of memory lines of the external memory device into a second plurality of memory lines of the memory dies based on received predicted memory commands.

13. The package device of claim 12, wherein the control circuitry is further configured to update the tag circuitry to associate the first plurality of memory lines with the second plurality of memory lines.

14. The package device of claim 1, wherein a first channel communicates memory commands from the processing device to the memory dies and the external memory device.

15. The package device of claim 1, wherein a first channel communicates memory commands from the processing device to the memory dies and a second channel communicates memory commands from the processing device to the external memory device.

16. A memory device comprising:
memory dies; and
a memory controller die connected to the memory dies, a processing device, and an external memory device, wherein the external memory device is external to the memory dies, and wherein the memory controller die is configured to control communication from the processing device to the memory dies and the memory device.

17. The memory device of claim 16, wherein the memory dies are vertically stacked on the memory controller die.

18. The memory device of claim 16, wherein the memory controller die is disposed on an interposer and the external memory device is disposed on the interposer, a substrate on which the interposer is disposed, or a printed circuit board connected to the interposer.

19. The memory device of claim 16, wherein the memory device is a high bandwidth memory device.

20. A computer system comprising:
a first processing device; and
an integrated circuit device coupled to the first processing device and comprising
a second processing device;
memory dies;
a memory device external to the memory dies; and
a memory controller die coupled to the second processing device, the memory dies, and the memory device, wherein the memory controller die is configured to control communication from the second processing device to the memory dies and the memory device.

21. The computer system of claim 20, wherein the memory dies are vertically stacked on the memory controller die.

22. The computer system of claim 20, wherein the memory dies and the memory controller die form a high bandwidth memory device.

23. The computer system of claim 20, wherein the integrated circuit device further includes an interposer, a substrate, and a printed circuit board, and wherein the memory controller die is disposed on the interposer, and wherein the memory device is disposed on one of the interposer, the substrate, and the printed circuit board.

24. A method comprising:
receiving, at a memory controller die of a package device, a memory command from a processing device, wherein the package device comprises memory dies, and wherein the memory controller die is connected to the memory dies and a memory device that is external from the memory dies; and
outputting the memory command to one of a memory die of memory dies based on the memory command being associated with the memory die or the memory device based on the memory command being associated with the memory device.

25. The method of claim 24, wherein the memory dies are vertically stacked on the memory controller die.

26. The method of claim 24, wherein the memory dies and the memory controller die are part of a high bandwidth memory device.

27. The method of claim 24 further comprising one of determining, via the memory controller die, that the memory command is associated with the memory die, or determining, via the memory controller die, that the memory command is associated with the memory device.
